(19) United States
(12) Patent Application Publication
(10) Pub. No.: US 2026/0221181 A1
(43) Pub. Date: Jul. 30, 2026

(54) SYSTEMS AND METHODS FOR INCREASING SENSE MARGIN OF MEMORY SENSING AMPLIFIERS

(71) Applicant: Samsung Electronics Co., Ltd., Suwon-si (KR)

(72) Inventors: Moumita DUTTA, Fremont, CA (US); Jaesoo AHN, San Jose, CA (US); Siwoo LEE, Saratoga, CA (US); Don Koun LEE, San Jose, CA (US); Sangmin HWANG, San Jose, CA (US); Anthony KANAGO, Fremont, CA (US); Nidhi AGRAWAL, Fremont, CA (US)

(21) Appl. No.: 19/298,177

(22) Filed: Aug. 12, 2025

Related U.S. Application Data
(60) Provisional application No. 63/751,266, filed on Jan. 29, 2025.

(51) Int. Cl. G11C 11/4094; G11C 11/4074; G11C 11/4091

(52) U.S. Cl. CPC G11C 11/4094; G11C 11/4074; G11C 11/4091

(57) ABSTRACT

Provided are systems, methods, and apparatuses for increasing the sense margin of memory sensing amplifiers in memory systems. In one or more examples, the disclosed systems, methods, and apparatuses include configuring a bitline selector to selectively couple a local bitline to a global bitline during a charge-sharing mode, the bitline selector including at least one transistor having a source terminal coupled to the local bitline and a drain terminal connected to a conductive connector that is connected to the global bitline; and forming an insulator between the bitline selector and underlying memory cells, the insulator to increase an inter-tier dielectric between the bitline selector and the underlying memory cells and between a capacitor area associated with the memory cells.

### CROSS-REFERENCE TO RELATED APPLICATIONS

This application claims the benefit of U.S. Provisional Patent Application Ser. No. 63/751,266, filed Jan. 29, 2025, which is incorporated by reference herein for all purposes.

### TECHNICAL FIELD

The disclosure relates generally to memory systems. In particular, the subject matter relates to increasing sense margin of memory sensing amplifiers.

### BACKGROUND

The present background section is intended to provide context only, and the disclosure of any concept in this section does not constitute an admission that said concept is prior art.

Random access memory (RAM) can include a computer's short-term memory that stores data a system processor is currently using. RAM may be referred to as read-write memory, main memory, or primary memory. RAM can include electronic computer memory that can be read and changed in any order, typically used to store working data and machine code. A random-access memory device allows data items to be read or written in almost the same amount of time irrespective of the physical location of data inside the memory, in contrast with other direct-access data storage media (such as hard disks and magnetic tape). RAM may be fabricated through a process involving silicon wafer fabrication, circuit layering, die preparation, testing, and module assembly.

### SUMMARY

In various embodiments, the systems and methods described herein include systems, methods, and apparatuses for increasing sense margin of memory sensing amplifiers. In some aspects, the techniques described herein relate to a system including: an array of memory cells; a global bitline; a local bitline; and a bitline multiplexor including: a bitline selector configured to selectively couple the local bitline to the global bitline, the bitline selector including at least one transistor having a source terminal coupled to the local bitline and a drain terminal connected to a conductive connector that is connected to the global bitline; and an insulator positioned adjacent to the bitline selector and adjacent to a memory cell.

In some aspects, the techniques described herein relate to a system, wherein: the bitline selector includes a first transistor and a second transistor, and a gate of the first transistor is merged with the gate of the second transistor.

In some aspects, the techniques described herein relate to a system, wherein: the bitline selector includes a first transistor and a second transistor, and a gate of the first transistor is connected to the gate of the second transistor at a wordline page region.

In some aspects, the techniques described herein relate to a system, wherein the insulator includes a dummy floating tier positioned adjacent to a transistor of the bitline selector.

In some aspects, the techniques described herein relate to a system, wherein the dummy floating tier includes a dummy transistor that is positioned adjacent to the at least one transistor of the bitline selector and a transistor of the memory cell.

In some aspects, the techniques described herein relate to a system, wherein: the bitline selector selectively couples the local bitline to the global bitline during a charge-sharing mode, and a charge sharing enable signal enables the bitline selector during the charge-sharing mode.

In some aspects, the techniques described herein relate to a system, wherein the charge sharing enable signal disables the bitline selector during a precharge mode.

In some aspects, the techniques described herein relate to a system, wherein the bitline selector is formed on one or more tiers of a memory module such that, during the charge-sharing mode, the bitline selector is activated to connect the local bitline electrically to the global bitline for transfer of a voltage level of the memory cell to a sense amplifier, the memory cell including a third transistor and a capacitor.

In some aspects, the techniques described herein relate to a system including: an array of memory cells; a local bitline; and a bitline multiplexor including: a keeper cell configured to selectively couple the local bitline to a bitline supply voltage, the keeper cell including at least one transistor having a source terminal coupled to the local bitline and a drain terminal connected to a conductive connector that is connected to the bitline supply voltage; and an insulator positioned adjacent to the keeper cell and adjacent to a memory cell.

In some aspects, the techniques described herein relate to a system, wherein: the keeper cell includes a first transistor and a second transistor, and a gate of the first transistor is merged with the gate of the second transistor.

In some aspects, the techniques described herein relate to a system, wherein: the keeper cell includes a first transistor and a second transistor, and a gate of the first transistor is connected to the gate of the second transistor at a wordline page region.

In some aspects, the techniques described herein relate to a system, wherein the insulator includes a dummy floating tier that includes a dummy transistor positioned adjacent to a transistor of the keeper cell and adjacent to a transistor of the memory cell.

In some aspects, the techniques described herein relate to a system, wherein the keeper cell selectively couples the local bitline to the bitline supply voltage during a precharge mode.

In some aspects, the techniques described herein relate to a system, wherein a precharge enable signal enables the keeper cell during the precharge mode.

In some aspects, the techniques described herein relate to a system, wherein the precharge enable signal disables the keeper cell during a charge-sharing mode.

In some aspects, the techniques described herein relate to a system, wherein the keeper cell is formed on one or more tiers of a memory module such that, during the precharge mode, the keeper cell is activated to connect the local bitline electrically to the bitline supply voltage to refresh the local bitline.

In some aspects, the techniques described herein relate to a method of fabricating a bitline multiplexor for a memory system, the method including: configuring a bitline selector to selectively couple a local bitline to a global bitline, the bitline selector including at least one transistor having a source terminal coupled to the local bitline and a drain terminal connected to a conductive connector that is connected to the global bitline; and forming an insulator adjacent to the bitline selector and adjacent to a memory cell, the insulator being configured to increase an inter-tier dielectric between the bitline selector and the memory cell.

In some aspects, the techniques described herein relate to a method, wherein: the bitline selector includes a first transistor and a second transistor, and a gate of the first transistor is merged with the gate of the second transistor.

In some aspects, the techniques described herein relate to a method, wherein: the bitline selector includes a first transistor and a second transistor, and a gate of the first transistor is connected to the gate of the second transistor at a wordline page region.

In some aspects, the techniques described herein relate to a method, wherein the insulator includes a dummy floating tier positioned adjacent to the bitline selector, the memory cell including a third transistor and the dummy floating tier including a dummy transistor.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

The systems and methods described herein include multiple advantages and benefits. For example, based on the systems and methods of a bitline multiplexor (mux), the sense margin is improved by reducing a load on the sense amplifiers (SAs) without changing (e.g. without increasing) the number of sense amplifiers. In fabrication processed, the bitline mux may be implemented based on using an additional mask compared to stacked memory modules without a bitline mux.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

FIG. 1 illustrates an example system in accordance with one or more implementations as described herein.

FIG. 2 illustrates a graph in accordance with one or more implementations as described herein.

FIG. 3 illustrates a schematic diagram in accordance with one or more implementations as described herein.

FIG. 4 illustrates a schematic diagram in accordance with one or more implementations as described herein.

FIG. 5 illustrates a schematic diagram in accordance with one or more implementations as described herein.

FIG. 6 illustrates a schematic diagram in accordance with one or more implementations as described herein.

FIG. 7 illustrates a schematic diagram in accordance with one or more implementations as described herein.

FIG. 8 illustrates a structure in accordance with one or more implementations as described herein.

FIG. 9 illustrates a structure in accordance with one or more implementations as described herein.

FIG. 10 illustrates a structure in accordance with one or more implementations as described herein.

FIG. 11 illustrates a structure in accordance with one or more implementations as described herein.

FIG. 12 illustrates a structure in accordance with one or more implementations as described herein.

FIG. 13 illustrates a structure in accordance with one or more implementations as described herein.

FIG. 14 illustrates a structure in accordance with one or more implementations as described herein.

FIG. 15 illustrates a structure in accordance with one or more implementations as described herein.

FIG. 16 illustrates a structure in accordance with one or more implementations as described herein.

FIG. 17 illustrates a structure in accordance with one or more implementations as described herein.

FIG. 18 illustrates a structure in accordance with one or more implementations as described herein.

FIG. 19 illustrates a structure in accordance with one or more implementations as described herein.

FIG. 20 illustrates a structure in accordance with one or more implementations as described herein.

FIG. 21 illustrates a structure in accordance with one or more implementations as described herein.

FIG. 22 illustrates a structure in accordance with one or more implementations as described herein.

FIG. 23 illustrates a structure in accordance with one or more implementations as described herein.

FIG. 24 illustrates a structure in accordance with one or more implementations as described herein.

FIG. 25 illustrates a structure in accordance with one or more implementations as described herein.

FIG. 26 illustrates a structure in accordance with one or more implementations as described herein.

FIG. 27 illustrates a structure in accordance with one or more implementations as described herein.

FIG. 28 illustrates a structure in accordance with one or more implementations as described herein.

FIG. 29 depicts a flow diagram illustrating an example method associated with the disclosed systems, in accordance with example implementations described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media includes all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random-access memory (CBRAM), phase-change random-access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random-access memory (FJG RAM), Millipede memory, racetrack memory, and/or the like.

In one embodiment, a volatile computer-readable storage medium may include random-access memory (RAM), dynamic random-access memory (DRAM), static random-access memory (SRAM), fast page mode dynamic random-access memory (FPM DRAM), extended data-out dynamic random-access memory (EDO DRAM), synchronous dynamic random-access memory (SDRAM), double data rate synchronous dynamic random-access memory (DDR SDRAM), double data rate type two synchronous dynamic random-access memory (DDR2 SDRAM), double data rate type three synchronous dynamic random-access memory (DDR3 SDRAM), Rambus dynamic random-access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random-access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of a hardware embodiment, a computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, a hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some examples, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some embodiments and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly referenced parts/modules are the only way to implement some of the embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth.

The provided description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Data processing may include data buffering, aligning incoming data from multiple communication lanes, forward error correction (FEC), etc. For example, data may be received by an analog front end (AFE), which can prepare the incoming data for digital processing. The digital portion of the transceivers (e.g., digital signal processor (DSP)) may provide skew management, equalization, reflection cancellation, and/or other functions. It is to be appreciated that the process described herein can provide many benefits, including saving both power and cost.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, SoC, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

It is understood that certain widely recognized structures, processes, and components may not be described in detail to prevent unnecessary complexity in the disclosure. The embodiments presented in this document are designed to accommodate a broad array of variations, modifications, and rearrangements that align with the principles and objectives of the disclosed subject matter. For instance, the described configurations may be adjusted or integrated in different ways to meet particular application requirements, and such adjustments are considered within the scope of the claims.

A memory system may employ dynamic random-access memory (DRAM) cells, each of which generally includes a transistor and a capacitor. In such cells, the transistor functions as a switch, controlling access to the capacitor that stores digital data as charge. Accordingly, the transistor serves as a gate that allows the reading or writing of the stored charge. When the stored charge is periodically refreshed to maintain data integrity, the reliable operation of these cells becomes highly important, particularly since even minor variations in the capacitor's voltage is based on detection with precision.

The present detailed description provides various embodiments of systems and methods for increasing the sense margin of sensing amplifiers in memory systems, such as dynamic random-access memory (DRAM) and stacked memory architectures. The described technology addresses challenges associated with signal integrity and sensing reliability in high-density memory configurations, such as those employing three-dimensional (3D) stacking techniques. While specific examples and configurations are described herein, these are provided for illustrative purposes only and are not intended to limit the scope of the described technology.

Over time, as memory architectures evolve to address demands for higher density and faster performance, particularly with the introduction of three-dimensional (3D) stacking techniques, challenges related to maintaining adequate signal levels have become more pronounced. The increase in cell density and the extension of interconnection networks can lead to higher parasitic capacitance, which reduces the voltage differences available during read operations. This reduction in voltage differences can make it more challenging for sense amplifiers to differentiate between the charged and discharged states of a memory cell, showing the importance of strategies to strengthen signal integrity and enhance the effectiveness of memory sensing operations.

Stacked memory architectures continue to encounter challenges as memory density continues to grow, particularly with the adoption of three-dimensional (3D) stacking techniques. Some memory systems rely on sense amplifiers (SAs) to detect and amplify voltage differences (ΔV) on bitlines during read operations. However, as the number of local bitlines (LBLs) connected to a global bitline (GBL) increases, parasitic capacitance on the bitline (Cb) rises, leading to a higher Cb/Cs ratio. This increase in parasitic capacitance reduces the voltage difference available for sensing, thereby diminishing the sense margin of the SAs. Reduced sense margin undermines the reliability of memory sensing operations, particularly in high-density configurations, where maintaining signal integrity becomes challenging. Some approaches to address this issue, such as increasing the number of SAs, result in higher area overhead and increased system costs, making them less feasible for modern memory architectures.

The concepts disclosed herein introduce systems and methods for improving the sense margin of SAs without increasing the number of SAs. The systems and methods leverage a bitline multiplexor (mux), which is implemented using upper tiers in stacked memory modules. The bitline mux can include a bitline selector and a keeper cell, which can work in tandem to reduce the load on the SAs during memory operations. The bitline selector enables selective electrical connection between LBLs and GBLs during charge-sharing mode, while the keeper cell maintains the bitline voltage (Vbl) during precharge mode. By electrically disconnecting unused LBLs from the GBLs, the bitline mux reduces the parasitic capacitance experienced by the SAs, thereby improving the sense margin. This approach eliminates the need for additional SAs, reducing area overhead and system complexity relative to the increased sense margin.

The systems can incorporate advanced configurations, including merged gates or connected gates for the transistors forming the bitline mux, to optimize saturation drive current (IDSAT). Additionally, the use of a dummy floating tier below the bitline mux or below the keeper cell increases inter-tier dielectric (ITD) thickness, improving electrical isolation and preventing charge leakage during memory operations. Optional configurations, including recessed silicon fingers with conformal metal contacts, provide further flexibility in adapting the bitline mux to given fabrication constraints. Aspects of the bitline mux offer a scalable and cost-effective solution for improving signal integrity and sensing reliability in high-density memory configurations.

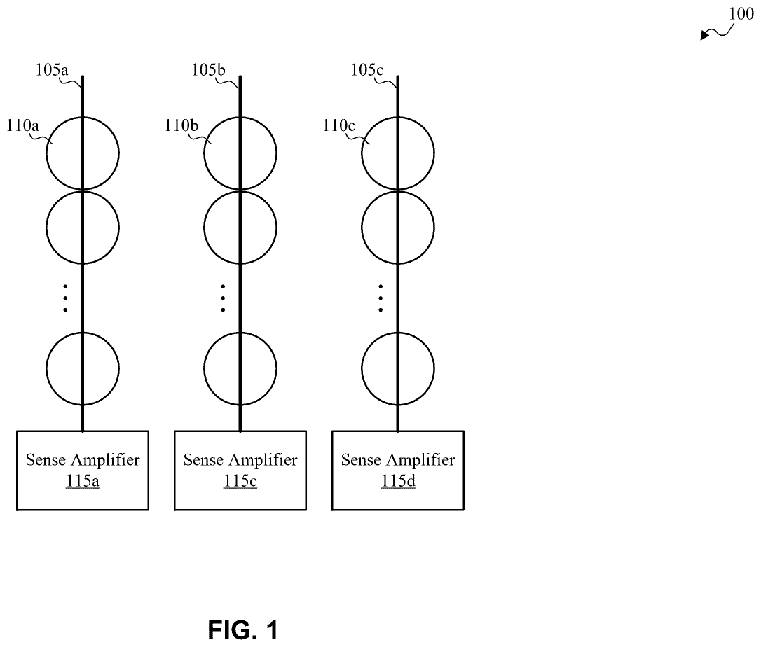

FIG. 1 depicts a system 100 including global bitlines (GBLs) 105 (e.g., GBL 105a, GBL 105b, GBL 105c, etc.), local bitlines (LBLs) 110 (e.g., LBL 110a of GBL 105a, LBL 110b of GBL 105b, LBL 110c of GBL 105c, etc.), and at least on sense amplifier (SA) 115 (e.g., where the organization of the bitlines and their connection to the sense amplifiers plays a role in performing data read and write operations in memory systems. In the illustrated example, the LBLs 110 are illustrated as cylindrical structures extending into the page from the perspective of FIG. 1. In some examples, the hierarchical structure of LBLs 110, GBLs 105, and SAs 115 depicted in FIG. 1 enables signal transmission and amplification in memory systems.

In the illustrated example, a given LBL 110 may be connected to a corresponding GBL 105. As shown, GBL 105a may be connected to one or more LBLs (e.g., at least LBL 110a). A given GBL 105 may transmit signals between the LBLs 110 and the SAs 115. Accordingly, the GBLs 105 are shown as vertical conductive paths positioned above the LBLs 110, showing the role of GBLs 105 in aggregating signals from multiple LBLs 110. As depicted the LBLs 110 may proceed into the page from the perspective of a viewer of FIG. 1.

As shown, the SAs 115 are depicted as rectangular blocks connected to the GBLs 105, and they are adapted to detect and amplify the voltage signals transmitted through the GBLs 105 during memory operations. For example, by comparing the voltage levels on the GBLs 105 to reference levels, the SAs 115 can determine the stored data values, thereby ensuring reliable memory operations.

In the illustrated example, the system 100 highlights the increasing density of LBLs 110 per GBL 105, a feature of stacked memory architectures. The depicted arrangement can lead to challenges, such as increased parasitic capacitance on the GBLs 105, which can reduce the voltage difference available for sensing, which can reduce the sensing margin of the SAs 115.

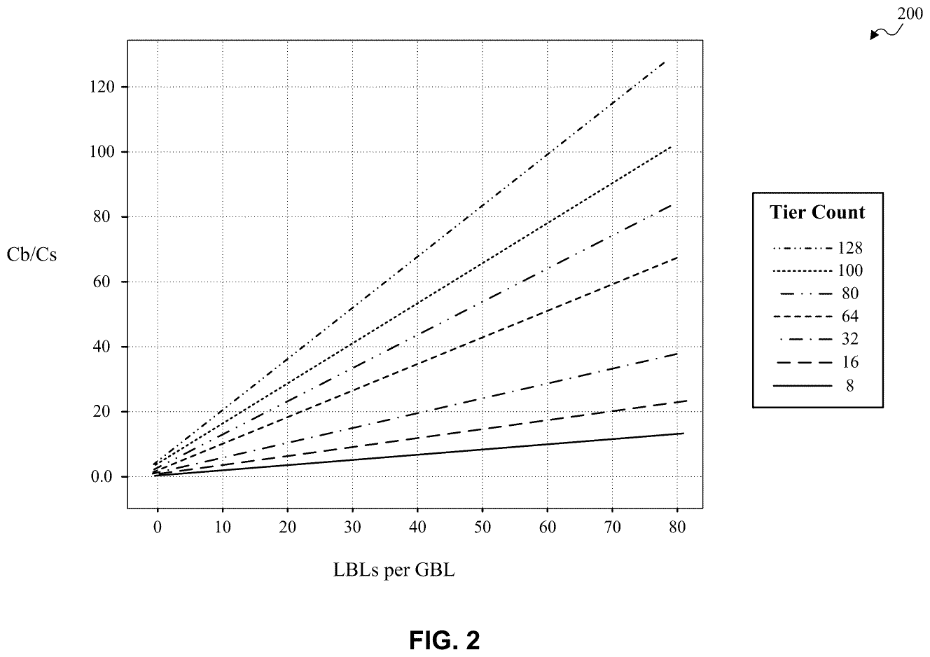

FIG. 2 depicts a graph 200 that characterizes the relationship between the ratio of bitline stray capacitance over memory cell capacitance (Cb/Cs) and the number of local bitlines per global bitline across varying tier counts in a process of record (POR) configuration. For example, as the depicted graph 200 illustrates, the Cb/Cs ratio increases as the number of LBLs per GBL grows, with distinct curves corresponding to different tier counts. The depicted graph 200 shows Cb/Cs for memory modules with 8 tiers, 16 tiers, 32 tiers, 64 tiers, 80 tiers, 100 tiers, and 128 tiers.

In the illustrated example, the x-axis represents the number of LBLs per GBL, which increases from 0 to 60, while the y-axis represents the Cb/Cs ratio, ranging from 0 to 120. Stacked memory modules can include multiple layers or tiers of memory cell arrays. Accordingly, each curve in the graph 200 may correspond to a specific tier count, including 8, 16, 32, 64, 80, 100, and 128 tiers. As shown, the tier count is indicated by a legend on the right side of the graph 200.

An electric charge stored in a capacitor may be read on a corresponding bitline and a variation in voltage attributed to the read electric charge may be amplified by an SA and then transmitted to an internal IO line pair. This variance ΔV in voltage on a bitline, attributed to data of a memory cell read on the bitline, may be determined based on the amount of electric charge accumulated in a memory cell capacitor, which may be given from the following expression: ΔV=(Vcc/2)·(1/(1+Cb/Cs)), where Cs can represent a capacitance of a memory cell capacitor and Cb can represent a stray capacitance of a bitline.

In some instances, the graph 200 illustrates that, as the LBLs per GBL increases, the Cb/Cs ratio rises more sharply for a given number of tiers. For example, the curve corresponding to 128 tiers may exhibit elevated Cb/Cs values across nearly all evaluated LBLs per GBL, whereas the curve corresponding to 8 tiers may show reduced values. The graph 200 depicts the influence of increasing LBLs per GBL and tier counts on parasitic capacitance as the Cb/Cs ratio increases.

In the illustrated example, the graph 200 highlights the challenges associated with high-density stacked memory architectures, where increasing the number of LBLs per GBL and tier counts exacerbates parasitic capacitance and leads to a reduction in the sense margin of sense amplifiers. Accordingly, the graph 200 serves as a visual representation of the utility of a bitline multiplexor (mux) in mitigating the effects of parasitic capacitance and enhancing memory sensing reliability.

With increasing cell array density, the number of LBLs per GBL increases, increasing the ratio of memory cell capacitor capacitance to bitline stray capacitance (Cb/Cs). Increasing the Cb/Cs ratio increases the SA load, which can reduce the sense margin of a given SA.

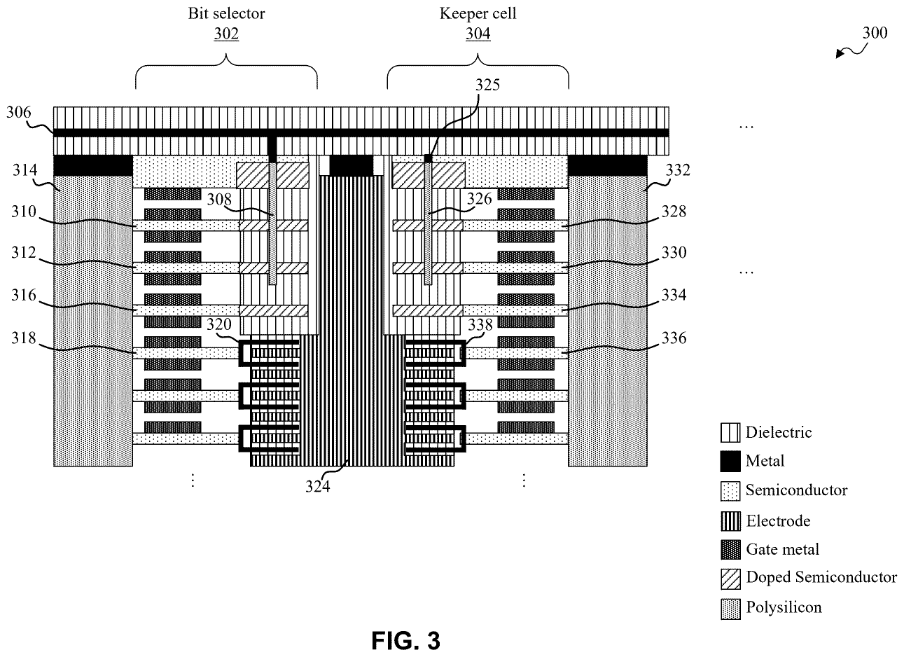

FIG. 3 illustrates a schematic diagram 300 of a bitline multiplexor (mux) integrated within a stacked memory module (e.g., 3D-DRAM). In the depicted example, the bitline mux may be configured to improve a sense margin of memory sensing amplifiers by reducing the load on the sense amplifiers without increasing the number of sense amplifiers. For example, the bitline multiplexor may include bitline selector 302 and keeper cell 304. The depicted memory module may include a global bitline (GBL) 306, connector 308, transistors of bitline selector 302 (e.g., transistor 310 and transistor 312), local bitline 314, transistor 316 (e.g., dummy floating tier), transistor 318 connected to capacitor 320, shared electrode 324, a bitline supply voltage (VBL) 325, connector 326, transistors of keeper cell 304 (e.g., transistor 328 and transistor 330), local bitline 332, transistor 334 (e.g., dummy floating tier), and transistor 336 connected to capacitor 338.

A given stacked memory module (e.g., depicted in FIG. 3) may include a stack of memory cell fingers (e.g., transistors). In some cases, one or more transistors towards the top of the stack (e.g., the first two or more transistors beneath the global bitline) may be configured to form a bitline mux (e.g., bitline selector and keeper cell). A bitline mux can include a circuit that selects one of multiple bitlines to be electrically connected to a GBL. The bitline mux may act as a switch to direct the data from a selected memory cell to the GBL, and from the GBL to the SA. The bitline mux may allow a processor to access a desired data stored in an indicated location within the memory array.

In the illustrated example, GBL 306 is positioned at the topmost layer of the diagram 300 and serve as a conductive path for transmitting signals between local bitline 314 and a sense amplifier of GBL 306. Similarly, GBL 306 serves as a conductive path for transmitting signals between local bitline 332 and the sense amplifier of GBL 306.

In some cases, GBL 306 may be connected to the bitline selector 302, which may be responsible for selectively connecting the local bitline 314 electrically to the GBL 306 or selectively disconnecting the local bitline 314 electrically from the GBL 306 during precharge and charge-sharing operations. Similarly, GBL 306 may be connected to the keeper cell 304, which may be responsible for selectively connecting or disconnecting the local bitline 332 electrically to/from the GBL 306 during precharge and charge-sharing operations. These selective electrical connections may reduce parasitic capacitance and improve voltage signal differentiation during read and write operations.

As depicted, LBL 314 and LBL 332 may extend vertically through the stacked memory module and may be connected respectively to individual memory cells. In the illustrated example, the transistors of bitline selector 302 are shown as semiconductor (e.g., silicon) fingers embedded within dielectric layers to ensure electrical isolation. As shown, these transistors may be configured to enable or disable an electrical connection between the local bitline 314 and the global bitline 306 based on control signals. In some examples, bit selector 302 may be enabled during a charge sharing mode. For example, a bitline selector control signal may enable transistors 310 and 312, electrically connecting bitline 314 to GBL 306 via connector 308. In some cases, transistor 310 and/or transistor 312 may include a semiconductor (e.g., silicon). In some cases, at least a portion (e.g., a tip) of transistor 310 and/or transistor 312 may include a doped semiconductor (e.g., n-doped semiconductor on drain of transistor 310 and/or transistor 312).

During a write operation, data may be transferred from GBL 306 to capacitor 320 based on bit selector 302 being enabled. Similarly, data stored in capacitor 320 may be delivered to LBL 314 by switching on transistor 318, and then from LBL 314 to GBL 306 based on bit selector 302 being enabled. In the depicted example, the transistor gates (e.g., depicted gate metal) of transistor 310 and transistor 312 may be connected. For example, depicted gate metal of transistor 310 and transistor 312 may be connected at a wordline pad region of the depicted memory module to optimize the drive current.

In some embodiments, each local bitline 314 may interface with both a bitline selector and a keeper cell. For example, a keeper cell different from keeper cell 304 may be connected to local bitline 314, and a bitline selector different from bitline selector 302 may be connected to local bitline 322. A given keeper cell may be configured to maintain a voltage level of a local bitline during a precharge mode, ensuring data integrity and preventing charge leakage by charging the local bitline to a reference voltage (Vbl) during precharge operations. When a bitline selector of a local bitline is enabled, then the keeper cell of that local bitline may be disabled. Similarly, when a keeper cell of a local bitline is enabled, then the bitline selector of that local bitline may be disabled.

In the illustrated example, keeper cell 304 may be configured to maintain a voltage level of local bitline 332 during precharge mode. In some examples, a control signal (e.g., different from a control signal of a bitline selector) may enable keeper cell 304 during a precharge mode. The precharge control signal may enable transistor 328 and 330, electrically connecting bitline 332 to VBL 325 via connector 326. In some cases, at least a portion (e.g., a tip) of transistor 328 and/or transistor 330 may include a doped semiconductor (e.g., n-doped semiconductor on drain of transistor 328 and/or transistor 330). It is noted that, while GBL 306 may connect to a sense amplifier, VBL 325 may connect to a voltage supply (e.g., voltage supply contacts, pins, wires, vias, etc.) of the stacked memory module.

As depicted, capacitors (e.g., capacitor 320) may be positioned adjacent to the local bitline 314 and may be responsible for storing data in the memory cells. Similarly, another set of capacitors (e.g., including capacitor 338) may be positioned adjacent to the local bitline 332 and may be responsible for storing data in additional memory cells. In some cases, each capacitor may include a first electrode connected to the transistor as shown, as well as a second electrode that is connected or is a part of shared electrode 324. The respective electrodes may be separated by dielectric material (e.g., high-K dielectric). Accordingly, the capacitors may be electrically isolated from the bitline selector 302 and keeper cell 304 to prevent unwanted charge sharing or leakage.

In the illustrated example, inter-tier dielectric (ITD) layers may be employed to enhance electrical isolation between the tiers of the stacked memory module. In some examples, a dummy floating tier may be included below the bitline selector 302 and/or keeper cell 304 to increase ITD thickness, thereby further improving data integrity and preventing field effects that could compromise memory operations. For example, transistor 316 may be electrically isolated and configured as a dummy floating tier below the transistors of bitline selector 302. Similarly, transistor 334 may be may be electrically isolated and configured as a dummy floating tier below the transistors of keeper cell 304.

The bitline mux configuration depicted in FIG. 3 may demonstrate a scalable and cost-effective approach to improving signal integrity and sensing reliability in high-density memory systems. In the illustrated example, by leveraging the selective connection of local bitlines 314 and 332 to the global bitline 306 and maintaining voltage levels during precharge mode, the bitline mux may enhance the sense margin of the memory sensing amplifiers while minimizing area overhead and system complexity.

In some cases, at least two memory cell fingers may be used to form bitline selector 302 or keeper cell 304. Any number of memory cell fingers may be used for bitline selector 302 or keeper cell 304 based on the drive current constraints of a given system. With some systems, the LBL may connect directly to a GBL. However, based on the concepts described herein, an LBL may connect to a GBL through a bitline selector or a keeper cell. Bitline selector 302 or keeper cell 304 may enable a given LBL to be selectable, where the LBL may be activated (e.g., turned on) via bitline selector 302 or keeper cell 304 and electrically connected to a sense amplifier (SA), or where the LBL may be inactivated (e.g., turned off) via bitline selector 302 or keeper cell 304 and electrically disconnected from the SA. Electrically disconnecting a given LBL from the SA may reduce the load on the SA, and reducing the load on the SA may increase the sense margin of the SA (e.g., increase the sensitivity of the SA in sensing voltage levels stored in capacitors of memory cells). Thus, the systems and methods described herein may improve sense margin of an SA while maintaining (e.g. without increasing) the number of SAs.

In the depicted example, the top two tiers may be configured as a two-finger bitline selector 302 or two-finger keeper cell 304. The transistors of bitline selector 302 and keeper cell 304 may include sources connected to respective local bitlines and drains connected to respective connectors (e.g., connector 308, connector 326). Dual finger configurations (e.g., two or more finger configurations) may be implemented to improve a saturated drive current (IDSAT) for the bitline mux (e.g., based on device constraints).

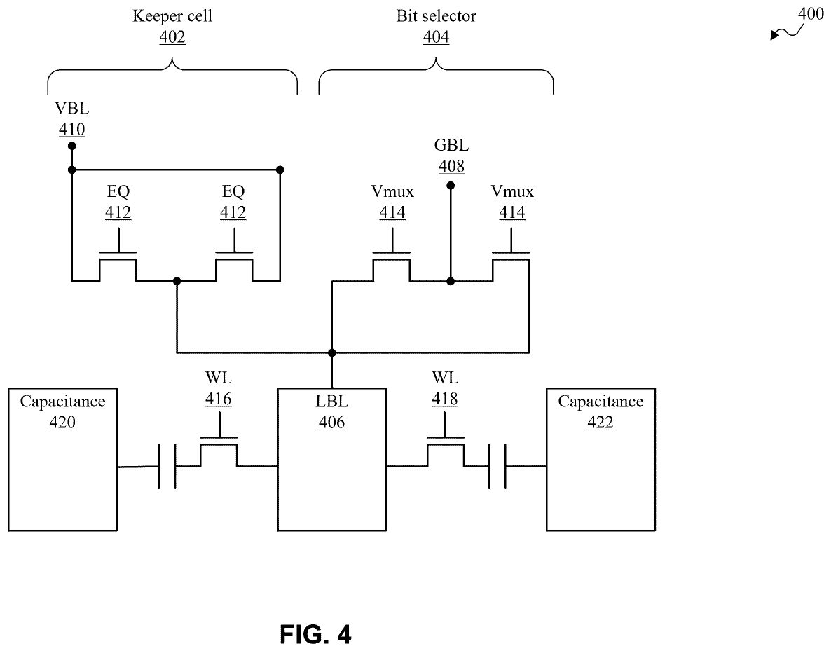

FIG. 4 depicts a schematic diagram 400 of a bitline multiplexor (mux) comprising a keeper cell 402, a bitline selector 404, a local bitline (LBL) 406, a global bitline (GBL) 408, a bitline supply voltage (VBL) 410, an enable signal (EQ) 412, a multiplexor voltage signal (VMUX) 414, and multiple wordlines (WL 416, WL 418, etc.), capacitance 420 (e.g., of keeper cell 402), and capacitance 422 (e.g., of bit selector 404). As shown, these components are configured to manage the electrical connection between the LBL 406 and the GBL 408 within a stacked memory module. For example, the depicted configuration is designed to improve the sense margin of memory sensing amplifiers by reducing the load on the sense amplifiers during memory operations.

In some examples, the keeper cell 402 may be coupled to the VBL 410 and controlled by the EQ 412. As shown, the keeper cell 402 may include two transistors, with each transistor possessing a common source connected to VBL 410 and a common drain connected to the LBL 406. Accordingly, the gates of these transistors may be controlled (e.g., enabled, disabled) by the EQ 412 signal. For example, EQ 412 may activate the keeper cell 402 during a precharge mode and/or deactivate the keeper cell 402 during a charge sharing mode. In the precharge mode, the keeper cell 402 may maintains the voltage level of the LBL 406 at a reference voltage (VBL 410), thereby ensuring data integrity and preventing charge leakage.

The illustrated example shows that the bitline selector 404 may be coupled to the GBL 408 and may be controlled by the VMUX 414 signal. As shown, similar to the keeper cell 402, the bitline selector 404 may comprise two transistors, with each transistor having a common source connected to the LBL 406 and a common drain connected to the GBL 408. The gates of these transistors are controlled by the VMUX 414 signal, which activates the bitline selector 404 during a charge-sharing mode. In this mode, as depicted, the bitline selector 404 electrically connects the LBL 406 to the GBL 408, enabling data to be read from or written to the memory cells associated with the LBL 406.

As illustrated further, the LBL 406 can serve as a conductive path for transmitting signals between memory cells and a sense amplifier. For example, the LBL 406 may be connected to multiple wordlines (WL 416, WL 418, etc.), which can control the activation of individual memory cells during read and write operations. As shown, the memory cells may be represented by capacitors (capacitance 420, capacitance 422) that store data as charge, and these capacitors may be electrically isolated from the bitline mux components by dielectric layers, prevents unwanted charge sharing or leakage.

In the depicted example, the configuration of FIG. 4 may demonstrate the hierarchical structure of a bitline mux. As shown, the keeper cell 402 and bitline selector 404 can work in tandem to optimize memory operations. For example, during a precharge mode, the keeper cell 402 can ensure that the LBL 406 is charged to the reference voltage (VBL 410) while the bitline selector 404 remains inactive. During a charge-sharing mode, the keeper cell 402 may be deactivated, and the bitline selector 404 may facilitate the electrical connection between the LBL 406 and the GBL 408, enabling data transfer.

As illustrated, the use of at least two transistors in both the keeper cell 402 and the bitline selector 404 may enhance the saturation drive current (IDSAT), thereby ensuring reliable operation even in high-density memory configurations.

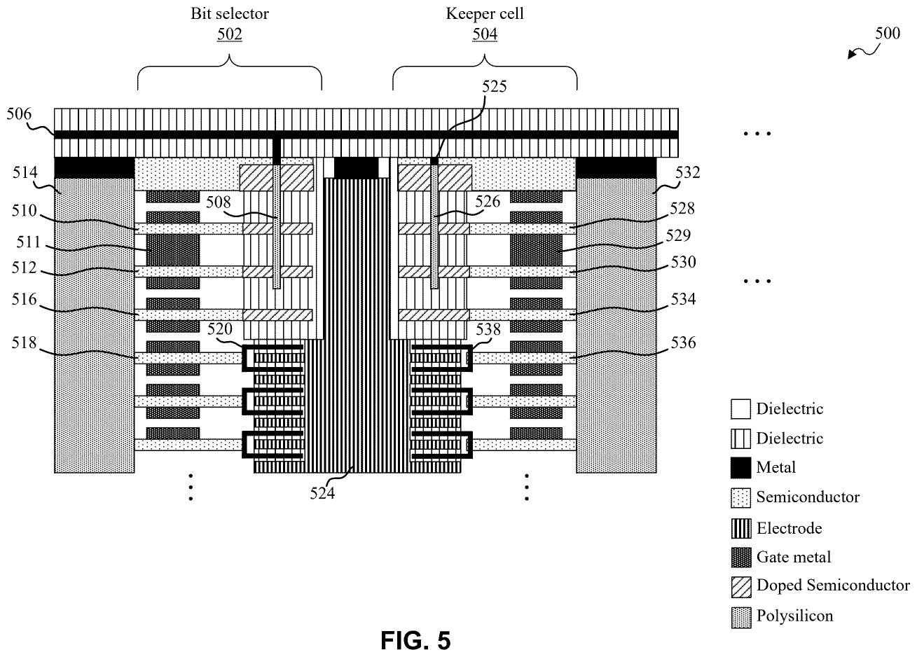

FIG. 5 illustrates a schematic diagram 500 of a bitline multiplexor (mux) configured to improve the sense margin of memory sensing amplifiers in high-density memory systems. For example, the bitline multiplexor may include bitline selector 502 and keeper cell 504. The depicted memory module may include a global bitline (GBL) 506, connector 508, transistors of bitline selector 502 (e.g., transistor 510 and transistor 512), merged gate 511, local bitline 514, transistor 516 (e.g., dummy floating tier, dummy transistor), transistor 518 connected to capacitor 520, shared electrode 524, a bitline supply voltage (VBL) 525, connector 526, transistors of keeper cell 504 (e.g., transistor 528 and transistor 530), merged gate 529, local bitline 532, transistor 534 (e.g., dummy floating tier, dummy transistor), and transistor 536 connected to capacitor 538.

It is noted that portions of white space depicted in FIG. 5 (e.g., portions of enclosed white space) may represent dielectric material. For example, the white space between transistor 510 and transistor 512, the white space between transistor 528 and transistor 530, etc., may depict spaces filled with dielectric material.

In some cases, the depicted configuration may utilize extended (non-recessed) silicon fingers in combination with metal contacts to enhance electrical connectivity and isolation between various components. For example, diagram 500 may depict an extended (e.g., non-recessed) silicon configuration. As shown, the drains of the transistors of the bitline selector 502 (e.g., transistors 510 and 512) may connect to a conductive contact (e.g., connector 508, a polysilicon connector). Similarly, the drains of the transistors of the keeper cell 504 (e.g., transistors 528 and 530) may be connected to another conductive contact (e.g., connector 526, a polysilicon connector).

In the illustrated example, the GBL 506 may serve as the primary conductive path for transmitting signals between local bitlines and sense amplifiers. As shown, the GBL 506 may be positioned at a topmost layer of the memory module and may be connected to bitline selector 502 via connector 508. As shown, VBL 525 may be positioned at a topmost layer of the memory module and may be connected to keeper cell 504 via connector 526. Accordingly, the local bitlines 514 and 532 may extend vertically through the stacked memory module to interface with individual memory cells and other components of the stacked memory module.

As shown, the gates of the transistors of bitline selector 502 (e.g., transistors 510 and 512) may be merged adjacent to the transistors of bitline selector 502 (e.g., merged gate 511). Similarly, the gates of the transistors of keeper cell 504 (e.g., transistors 528 and 530) may be merged adjacent to the transistors of keeper cell 504 (e.g., merged gate 529). It is noted that the resistance associated with the gate metal increases based on connecting the gates in the wordline pad region (e.g., based on distance between the junction of the connected gates). Accordingly, the merged gates may benefit from a lower resistance compared to gates connected remotely (e.g., at a wordline pad region). Accordingly, the gates of the bitline selector 502 and/or keeper cell 504 may be merged, facilitating control signals for activation and deactivation of local bitlines during various memory operations and enabling precise control during precharge operations.

In some examples, the bitline selector 502 may be configured to selectively connect or disconnect the local bitline 514 from the GBL 506 during charge-sharing operations. As shown, the transistor fingers of the bitline selector 502 (e.g., transistor 510, transistor 512) may be extended and, in some cases, connected to a metal contact (e.g., connector 508) that ensures a reliable electrical connection with the GBL 506.

As depicted, the keeper cell 504 may be responsible for maintaining the voltage level of the local bitline 514 during precharge mode to ensure data integrity and to prevent charge leakage. In some cases, similar to the bitline selector 502, the transistors of the keeper cell 504 may be extended and connected to a metal contact (e.g., connector 526).

In the illustrated example, capacitor 520 may be connected to transistor 518 and may be responsible for storing data for one memory cell. For example, each capacitor may include a first electrode connected to a transistor and shared electrode 524 separated by a dielectric material from the individual electrodes. Moreover, as shown, the capacitors may be electrically isolated from the bitline selector 502 and keeper cell 504 to prevent any unwanted charge sharing or leakage.

The depicted configuration may provide a thicker inter-tier dielectric (ITD) between the bitline selector 302 and keeper cell 304, and the memory cells below the bitline selector 302 and keeper cell 304. For example, transistor 516 and transistor 534 may be configured as dummy floating tiers to increase the respective thickness of the inter-tier dielectric between the bitline selector 302 and keeper cell 304, and the memory cells below the bitline selector 302 and keeper cell 304, preventing field effects that could compromise memory operations.

The memory module of FIG. 5 may demonstrate a scalable and cost-effective approach to improving signal integrity and sensing reliability in high-density memory systems by leveraging metal contacts and merged gate connections, reducing the load on sense amplifiers and enhancing the sense margin without necessitating an increased number of sense amplifiers.

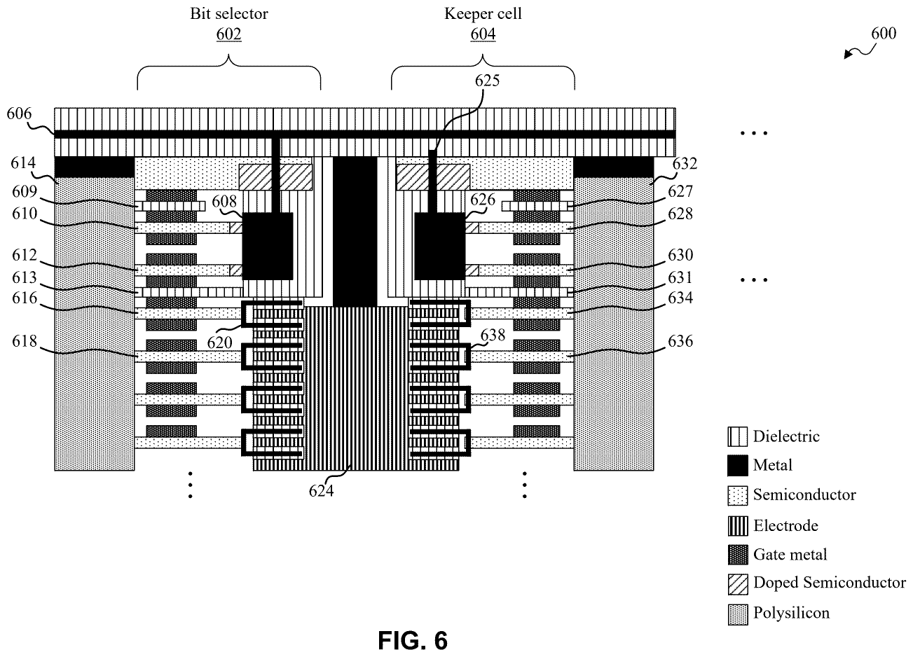

FIG. 6 illustrates a schematic diagram of a bitline multiplexor (mux) configured to improve the sense margin of memory sensing amplifiers in high-density memory systems. For example, the bitline multiplexor may include bitline selector 602 and keeper cell 604. The depicted memory module may include a global bitline (GBL) 606, contact 608, dielectric 609, transistors of bitline selector 602 (e.g., transistor 610 and transistor 612), dielectric 613, local bitline 614, transistor 616 (e.g., dummy floating tier), transistor 618 connected to capacitor 620, shared electrode 624, a bitline supply voltage (VBL) 625, contact 626, dielectric 627, transistors of keeper cell 604 (e.g., transistor 628 and transistor 630), local bitline 632, dielectric 631, local bitline 632, transistor 634 (e.g., dummy floating tier), and transistor 636 connected to capacitor 638.

In the illustrated example, the bitline selector 602 may be configured to selectively connect or disconnect local bitline 614 to GBL 606 during charge-sharing operations. As shown, the recessed transistors of bitline selector 602 may be connected to a conformal metal contact (e.g., contact 608), which in turn may ensure reliable electrical connectivity between local bitline 614 and GBL 606. In some examples, contact 608 may be connected to GBL 606 through a vertical conductive connector. Accordingly, the configuration may allow the bitline selector 602 to connect the local bitline 614 electrically to the GBL 606 when bitline selector 602 is activated, thereby facilitating data transfer during read and write operations.

Furthermore, as depicted, the keeper cell 604 may be configured to maintain the voltage level of the local bitline 632 during a precharge mode. In some instances, the recessed transistors of keeper cell 604 may be connected to a conformal metal contact (e.g., contact 626), which may be connected to VBL 625. Contract 626 may ensure that the keeper cell 604 has the capability to charge the local bitline 632 to a reference voltage (e.g., VBL 325) during precharge operations.

In the illustrated example, dielectric 609 may be positioned between the gate metal above transistor 610 (e.g., topmost gate metal of bit selector 602). In some cases, the gate metal may surround or envelop at least a portion of dielectric 609. As shown, dielectric 613 may be positioned between the gate metal between transistor 612 and transistor 616. In some cases, this gate metal may surround or envelop at least a portion of dielectric 613. In some cases, dielectric 609 and/or dielectric 613 may increase the thickness of the inter-tier dielectric of bit selector 602, further improving data integrity and preventing field effects that could compromise memory operations, ensuring that bitline selector 602 operates reliably without interference from adjacent components.

In the illustrated example, dielectric 627 may be positioned between the gate metal above transistor 628 (e.g., topmost gate metal of keeper cell 604). In some cases, this gate metal may surround or envelop at least a portion of dielectric 627. As shown, dielectric 631 may be positioned between the gate metal between transistor 630 and transistor 634. In some cases, this gate metal may surround or envelop at least a portion of dielectric 631. In some cases, dielectric 627 and/or dielectric 631 may increase the thickness of the inter-tier dielectric of keeper cell 604, further improving data integrity and preventing field effects that could compromise memory operations, ensuring that keeper cell 604 operates reliably without interference from adjacent components.

In the illustrated example, the recessed silicon configuration depicted in FIG. 6 may demonstrate a scalable and cost-effective approach to improving signal integrity and sensing reliability in high-density memory systems. As shown, by leveraging conformal metal contacts and precise gate connections, the bitline mux may effectively reduce the load on sense amplifiers, thereby enhancing the sense margin without necessitating an increased number of sense amplifiers.

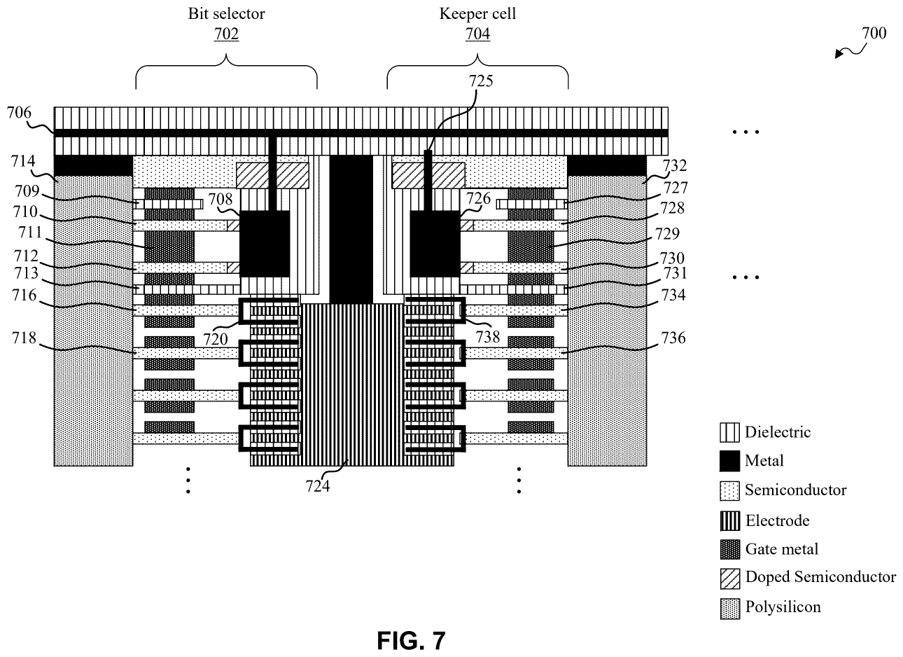

FIG. 7 may depict a schematic diagram 700 of a bitline multiplexor (mux) configured for dynamic random-access memory (DRAM) is depicted. For example, the bitline multiplexor may include bitline selector 702 and keeper cell 704. The depicted memory module may include a global bitline (GBL) 706, contact 708, dielectric 709, transistors of bitline selector 702 (e.g., transistor 710 and transistor 712), merged gate 711, dielectric 713, local bitline 714, transistor 716 (e.g., dummy floating tier), transistor 718 connected to capacitor 720, shared electrode 724, contact 726, dielectric 727, transistors of keeper cell 704 (e.g., transistor 728 and transistor 730), merged gate 729, dielectric 731, local bitline 732, transistor 734 (e.g., dummy floating tier), and transistor 736 connected to capacitor 738.

In the illustrated example, the bitline selector 702 may be configured to selectively connect or disconnect local bitline 714 to GBL 706 during charge-sharing operations. As shown, the recessed transistors of bitline selector 702 may be connected to a conformal metal contact (e.g., contact 708), which in turn may ensure reliable electrical connectivity between local bitline 714 and GBL 706. In some examples, contact 708 may be connected to GBL 706 through a vertical conductive connector. Accordingly, the configuration may allow the bitline selector 702 to connect the local bitline 714 electrically to the GBL 706 when bitline selector 702 is activated, thereby facilitating data transfer during read and write operations.

Furthermore, as depicted, the keeper cell 704 may be configured to maintain the voltage level of the local bitline 732 during a precharge mode. In some instances, the recessed transistors of keeper cell 704 may be connected to a conformal metal contact (e.g., contact 726), which may be connected to VBL 725. Contract 726 may ensure that the keeper cell 704 has the capability to charge the local bitline 732 to a reference voltage (e.g., VBL 325) during precharge operations.

In the illustrated example, dielectric 709 may be positioned between the gate metal above transistor 710 (e.g., topmost gate metal of bit selector 702). In some cases, the gate metal may surround or envelop at least a portion of dielectric 709. As shown, dielectric 713 may be positioned between the gate metal between transistor 712 and transistor 716. In some cases, this gate metal may surround or envelop at least a portion of dielectric 713. In some cases, dielectric 709 and/or dielectric 713 may increase the thickness of the inter-tier dielectric of bit selector 702, further improving data integrity and preventing field effects that could compromise memory operations, ensuring that bitline selector 702 operates reliably without interference from adjacent components.

In the illustrated example, dielectric 727 may be positioned between the gate metal above transistor 728 (e.g., topmost gate metal of keeper cell 704). In some cases, this gate metal may surround or envelop at least a portion of dielectric 727. As shown, dielectric 731 may be positioned between the gate metal between transistor 730 and transistor 734. In some cases, this gate metal may surround or envelop at least a portion of dielectric 731. In some cases, dielectric 727 and/or dielectric 731 may increase the thickness of the inter-tier dielectric of keeper cell 704, further improving data integrity and preventing field effects that could compromise memory operations, ensuring that keeper cell 704 operates reliably without interference from adjacent components.

As shown, the gates of the transistors of bitline selector 702 (e.g., transistors 710 and 712) may be merged adjacent to the transistors of bitline selector 702 (e.g., merged gate 711). Similarly, the gates of the transistors of keeper cell 704 (e.g., transistors 728 and 730) may be merged adjacent to the transistors of keeper cell 704 (e.g., merged gate 729). It is noted that the resistance associated with the gate metal increases based on connecting the gates in the wordline pad region (e.g., based on distance between the junction of the connected gates). Accordingly, the depicted merged gates may benefit from a lower resistance compared to gates connected remotely (e.g., at a wordline pad region). Accordingly, the gates of the bitline selector 702 and/or keeper cell 704 may be merged, facilitating control signals for activation and deactivation of local bitlines during various memory operations and enabling precise control during precharge operations.

By leveraging recessed transistors, conformal metal contacts, and merged gates, the bitline mux depicted in FIG. 7 demonstrates a scalable and cost-effective approach to improving signal integrity and sensing reliability in high-density memory systems. As shown, such a configuration may reduce the load on sense amplifiers, thereby enhancing the sense margin without necessitating an increased number of sense amplifiers.

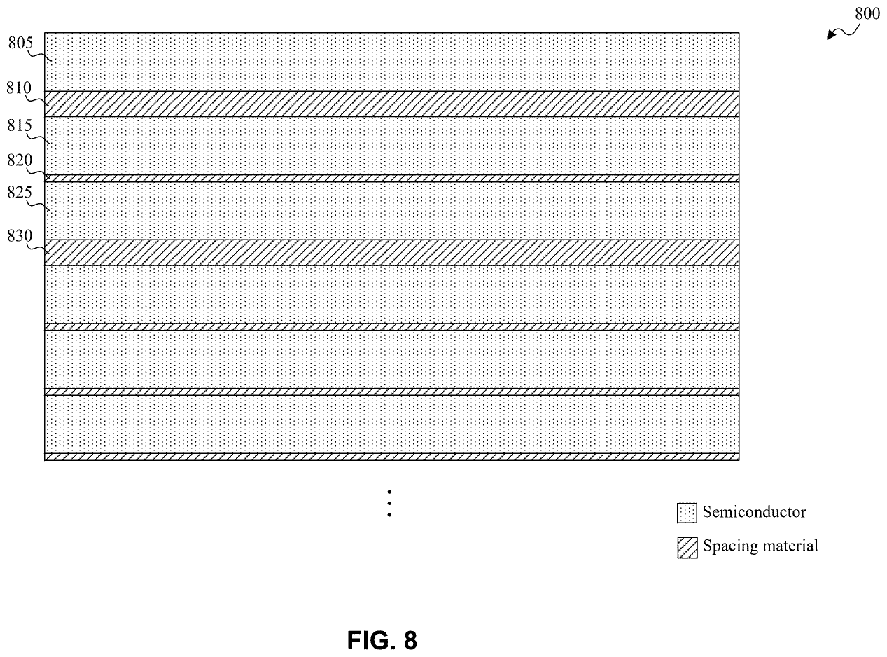

FIG. 8 illustrates a structure 800 of interleaved semiconductor epitaxial layers utilized in the fabrication process for a bitline multiplexor (mux). For example, the depicted structure comprises alternating layers of a semiconductor (e.g., 805, 815, 825, etc.) and spacing material (e.g., 810, 820, 830, etc.), where each layer contributes properties to the overall configuration. In some cases, the semiconductor may include silicon and the spacing material may include silicon germanium.

In the illustrated example, layers 805, 815, and 825 in the stack are thicker (e.g., ranging from approximately 50 to 90 nanometers (nm)) compared to layers 810, 820, and 830. These layers provide structural integrity and serve as the primary material for forming transistor channels and other active components in the bitline mux. The silicon layers are interspersed with thinner silicon germanium layers.

In some examples, some of the silicon germanium layers (e.g., two silicon germanium layers) in the stack may be thicker than other silicon germanium layers. For example, layers 810 and 830 may be thicker than layer 820 and other silicon germanium layers. In some cases, layers 810 and 830 may be a first thickness (e.g., approximately 30 nm), while layer 820 and/or other silicon germanium layers may be a second thickness (e.g., between 5 nm and 15 nm) different from the first thickness.

As shown, the thicker silicon germanium layers may be positioned within the stack to create differentiated spacing between some of the silicon layers. This spacing may facilitate the deposition of materials during subsequent fabrication steps, enabling precise control over electrical isolation and gate formation, etc.

In some examples, the epitaxial layer stack shown in FIG. 8 demonstrates a scalable and adaptable approach to fabricating high-density memory systems. By leveraging the alternating semiconductor configuration, the fabrication process achieves precise control over layer thickness and material properties, enhancing the performance of the bitline mux and the components associated with the bitline mux.

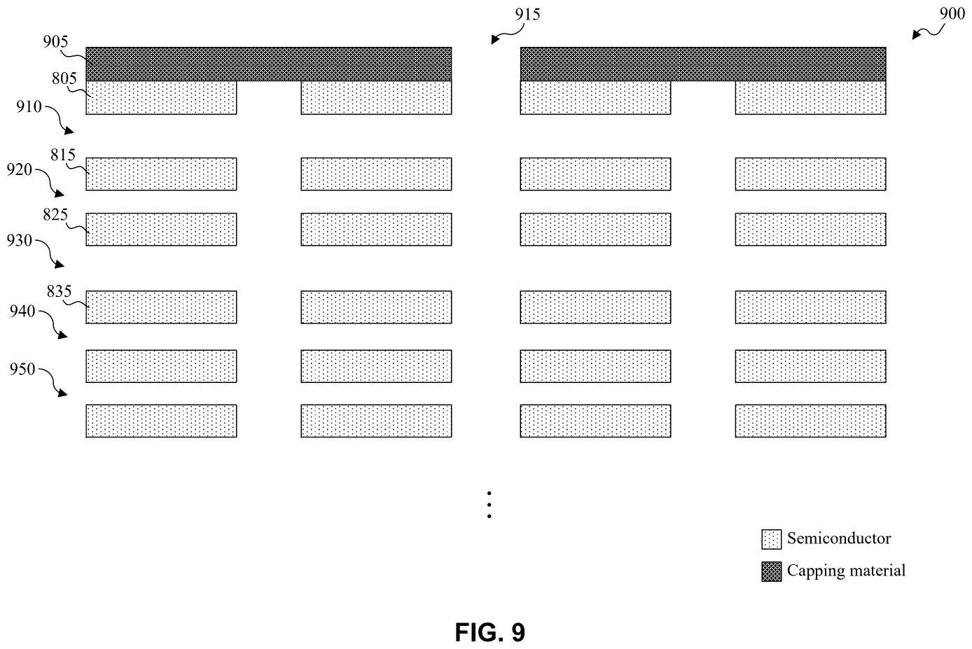

FIG. 9 illustrates a structure 900 based on a thinning process implemented to achieve differentiated spacing between semiconductor layers. For example, a stack comprising alternating silicon layers and silicon germanium (SiGe) layers is depicted, where the SiGe layers have been selectively etched away to leave behind silicon layers with varying inter-layer spacing. The structure 900 plays a role in enabling control over layer thickness and material properties during the fabrication of high-density memory systems. As shown, the depicted fabrication process may result in the silicon layers being divided into two or more segments with gaps between the segments (e.g., four segments with three gaps being depicted).

The semiconductor at layers 805, 815, 825, etc., may be thinned. For example, a portion of each layer of silicon may be etched, etc. As shown, the thickness (e.g., vertical thickness) of the layers 805, 815, 825, etc., may be reduced based on the thinning. In some cases, an oxide (e.g., gate oxide) may be deposited on one or more surfaces of the semiconductor at 805, 815, 825, etc. In some examples, a capping material (e.g., capping material 905) may be added to a top layer of structure 900 (e.g., on top of layer 805, etc.).

The spacing material at layers 810, 820, 830, etc., may be removed, creating spaces 910, 920, 930, 940, etc. As shown, the removal process (e.g., etching process) may form a gap 915 between the elements of structure 900. As shown, space 910 and space 930 may be greater than the other spaces (e.g., space 920, space 940, space 950, etc.) based on the thicker spacing material at layers 810 and 830.

In the illustrated example, the remaining silicon layers are depicted as structural elements following the removal of the spacing material. As shown, the thinning process results in two distinct spacing configurations between the silicon layers, namely a first spacing (e.g., of 85 nm at spaces 910 and 930) and a second spacing (e.g., of 65 nm at spaces 920, 940, 950, etc.). The differentiation in spacing may be attributed to the original thicknesses of the respective spacing material prior to removal.

In the illustrated example, the SiGe thinning process depicted in FIG. 9 demonstrates a scalable and adaptable approach to fabricating high-density memory systems. For example, by leveraging the alternating configuration and control over layer thinning, the process may achieve differentiated spacing that plays a significant role in optimizing the electrical performance and structural integrity of the fabricated components.

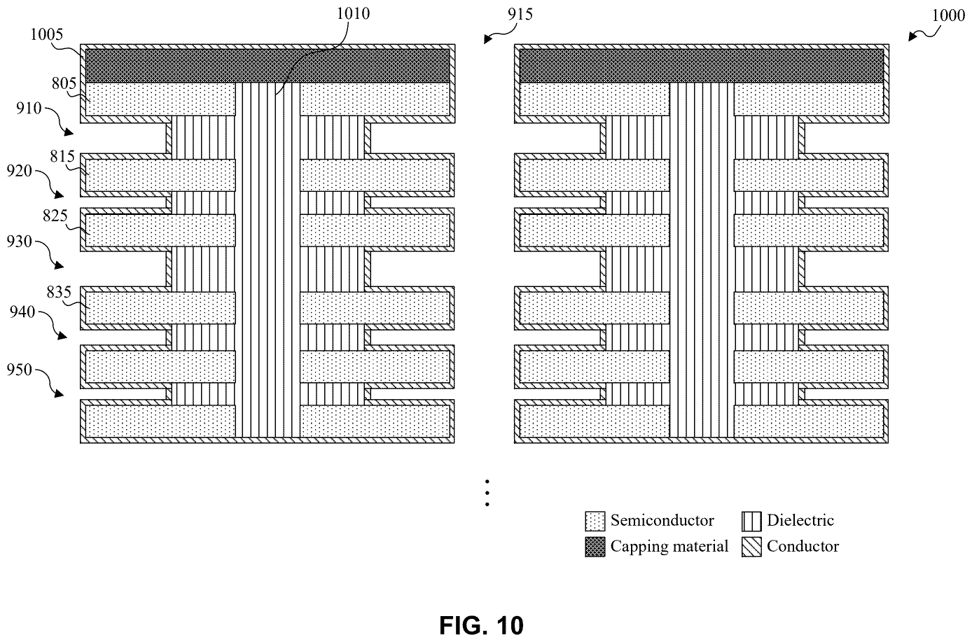

FIG. 10 illustrates a structure 1000 of a stacked memory module. In some cases, FIG. 10 may depict at least a portion of a fabrication process of a stacked memory module configured with a bitline multiplexor (mux), where the bitline mux may include a bitline selector and a keeper cell.

In the illustrated example, a conductive material (e.g., conductor 1005) may be added to or deposited over one or more exposed surfaces of structure 1000. In some cases, conductor 1005 may include a metal (e.g., titanium nitride). In some instances, this deposition process includes the addition of dielectric layers (e.g., dielectric 1010) over one or more surfaces of structure 1000. As shown, the fabrication process may include filling in one or more gaps between the segments of silicon layers with dielectric 1010, thereby contributing to the structural integrity and electrical performance of the stacked memory module. As shown, gap 915 may remain based on the addition of conductor 1005 and dielectric 1010.

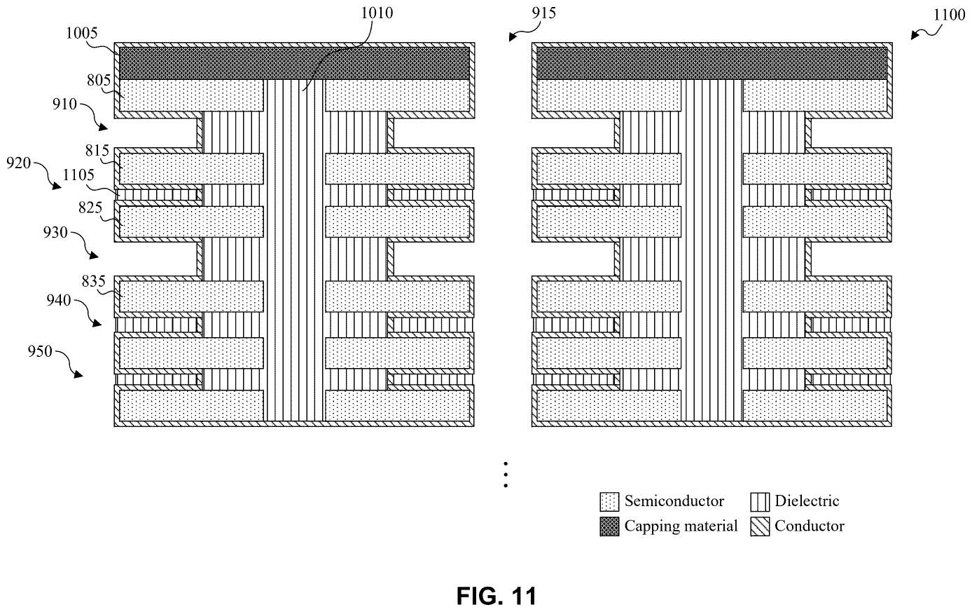

FIG. 11 illustrates a structure 1100 associated with the fabrication of a stacked memory module. In some cases, FIG. 11 may depict at least a portion of a fabrication process of a stacked memory module configured with a bitline multiplexor (mux), where the bitline mux may include a bitline selector and a keeper cell.

In the illustrated example, dielectric 1105 may be added to space 920. As shown, a similar dielectric (e.g., same dielectric) may be added to other thinner spaces of structure 1100 (e.g., to space 920, space 940, etc.), where the thinner spaces may be based on the thinner layers 820, etc. (e.g., thinner germanium silicon layers). In some cases, dielectric 1105 may include an electrical insulator or dielectric material (e.g., an oxide dielectric, a nitride dielectric, etc.).

By leveraging the hierarchical structure of a stacked memory module, structure 1100 may demonstrate a cost-effective solution for implementing a bitline mux, improving signal integrity and sensing reliability in high-density memory configurations, and enhancing the sense margin of memory sensing amplifiers while simultaneously minimizing area overhead and system complexity.

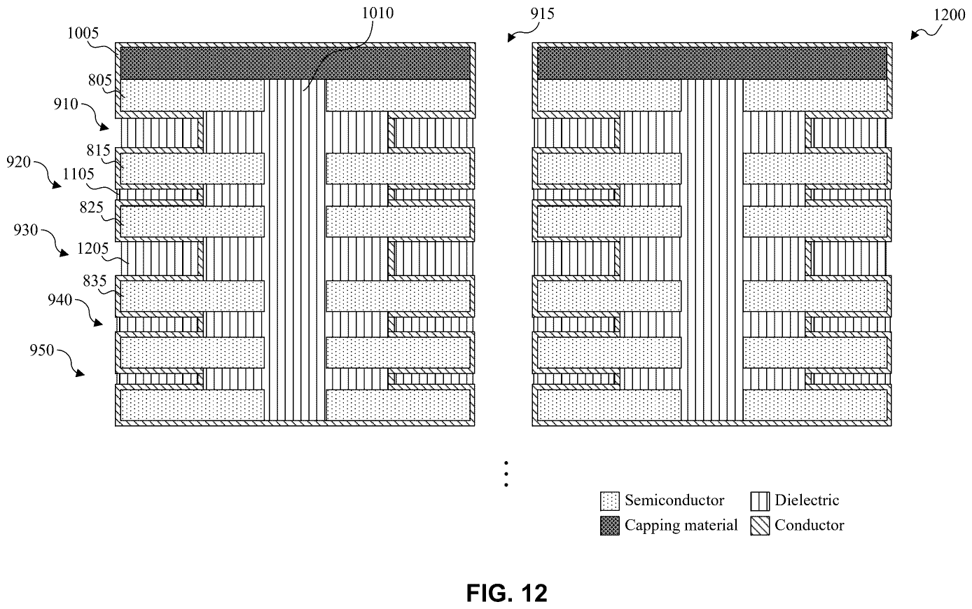

FIG. 12 may depict a structure 1200 associated with the fabrication of a stacked memory module is depicted. In some cases, FIG. 12 may depict at least a portion of a fabrication process of a stacked memory module configured with a bitline multiplexor (mux), where the bitline mux may include a bitline selector and a keeper cell.

In the illustrated example, dielectric material may be deposited between the thicker spaces (e.g., space 910, space 930, etc.) that are formed based on the thicker layers 810, 830, etc. (e.g., thicker silicon germanium layers). In some examples, dielectric 1205 may be added to space 930. In some cases, the dielectric in the thicker spaces may be different from the dielectric in the thinner spaces. For example, dielectric 1105 in space 920 may include a first dielectric (e.g., silicon dioxide, silicon nitride, etc.) and dielectric 1205 in space 930 may include a second dielectric (e.g., silicon oxycarbide (SiOC)) different from dielectric 1105 (e.g., an oxide dielectric). In some cases, the thicker layer of space 930 may be formed to facilitate adding dielectric 1205 to the thicker spaces (e.g., space 910, space 930, etc.) and separately adding dielectric 1105 to the thinner spaces (e.g., space 920, space 940, space 950, etc.).

Accordingly, structure 1200 highlights the deposition of a second dielectric material, such as silicon oxycarbide (SiOC), between larger spaces formed based on the thicker silicon germanium layers. For example, these thicker silicon germanium layers are strategically formed to accommodate the introduction of the second dielectric material, which differs from the first dielectric material. This dual-dielectric approach enhances electrical isolation between the silicon layers and supports the reliable operation of the memory system.

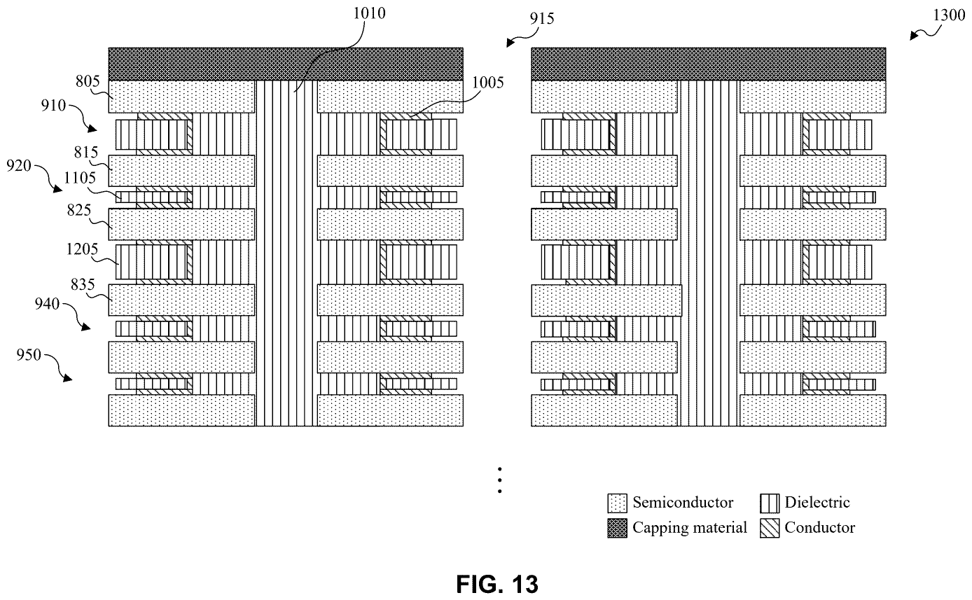

FIG. 13 depicts a structure 1300 of a stacked memory module configured with local bitlines (LBL) and global bitlines (GBL) that enhance the sense margin via a bitline multiplexor. For example, the figure illustrates the removal of an outer portion of a titanium nitride layer, specifically the upper or top portion of the titanium nitride deposition as depicted in FIG. 10. This removal process plays a significant role in the fabrication of the bitline multiplexor and aids in achieving improved electrical isolation and enhanced signal integrity within the stacked memory module.

In the illustrated example, at least a portion of the previously added conductive material (e.g., conductor 1005) may be removed from one or more exposed surfaces of structure 1300. In some cases, an insulating oxide material (e.g., gate oxide) may remain on one or more surfaces of at least the semiconductor at 805, 815, 825, etc. (e.g., remain after removal of the portion of the conductive material). In some cases, a gate oxide may be deposited over semiconductors of structure 1300 (e.g., semiconductor layers 815, 825, etc.), where the gate oxide may separate or insulate these semiconductors from the portions of conductor 1005 around the same semiconductors. In some cases, the conductive material above and/or below the semiconductor layers 815, 825, etc., may be configured as gate metal and the semiconductors as transistors of a stacked memory module configured with a bitline mux.

Accordingly, structure 1300 depicts the deposition and subsequent removal of the conductive material (e.g., conductor 1005, titanium nitride), where the conductive material is employed during the fabrication process. For example, the removal of the outer portion of the conductor 1005 exposes underlying dielectric layers and other structural elements, thereby enabling precise control over electrical isolation and gate formation. In this manner, the process plays a role in the integration of the bitline multiplexor, which comprises a bitline selector and a keeper cell.

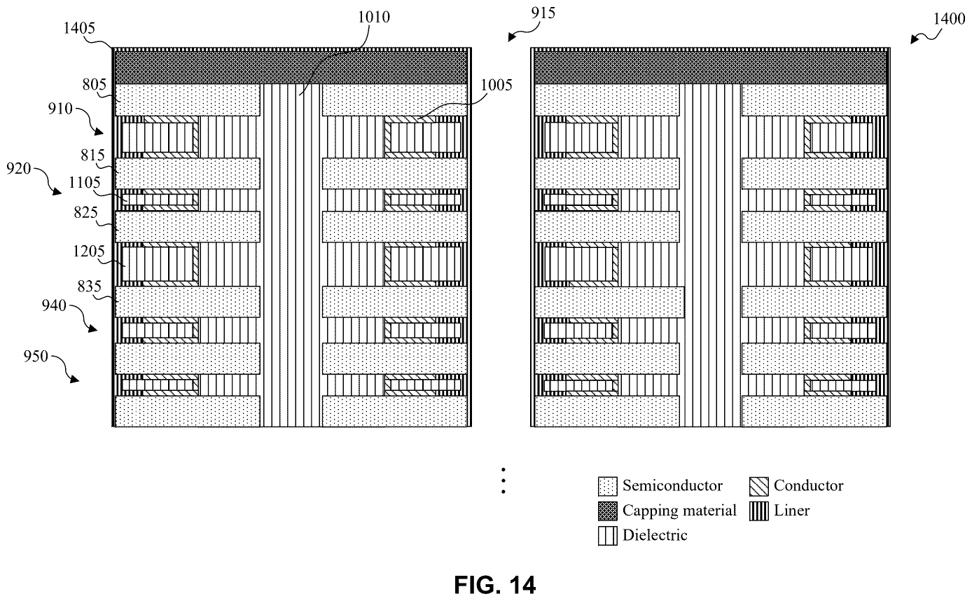

FIG. 14 may depict a structure 1400 associated with the fabrication of a bitline multiplexor (mux) integrated within a stacked memory module. In some cases, the depicted configuration includes elements arranged in tiers to enable the fabrication of a bitline mux that includes a bitline selector and a keeper cell.

In the illustrated example, a lining material (e.g., liner 1405) may be added to or deposited over one or more exposed surfaces of structure 1400. In some cases, liner 1405 may include an electrical insulator or dielectric (e.g., silicon nitride).

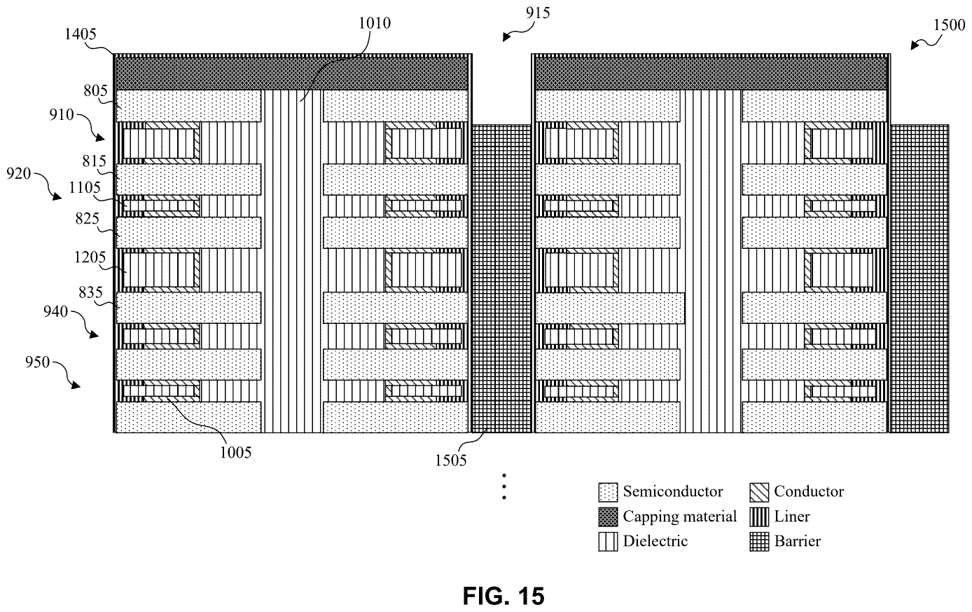

FIG. 15 depicts a structure 1500 associated with the fabrication of a bitline multiplexor (mux) integrated within a stacked memory system. In some cases, structure 1500 highlights the addition of a material employed to fill a gap between stacked tiers.

In the illustrated example, a barrier material (e.g., barrier 1505) may be deposited in gap 915 between the tiers of structure 1500. As shown, the barrier material may be added to other gaps (e.g., to the right of the right-most elements depicted). Although the illustrated example does not depict the barrier metal being applied to a gap to the left of the left-most elements (e.g., based on the placement of multiple reference numbers there), it is understood that the barrier material may be added to a gap to the left of the left-most elements as well. Also, additional tiers may repeat to the left and/or to the right of the depicted structure 1500, with barrier material filling gaps between those tiers.

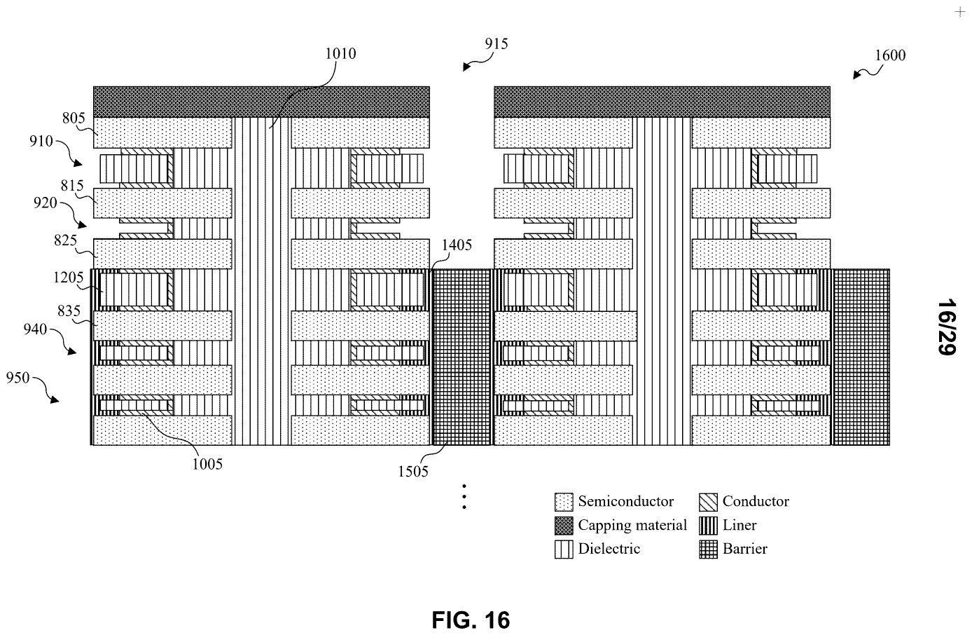

FIG. 16 illustrates a structure 1600 associated with the fabrication of a bitline multiplexor (mux) integrated within a stacked memory module. The arrangement of structure 1600 is designed to improve the sense margin of memory sensing amplifiers by reducing the load on the sense amplifiers without increasing their number.

In the illustrated example, at least a portion of the lining material (e.g., liner 1405) may be removed. For example, liner 1405 (e.g., a layer of silicon nitride) may be removed from the top tiers of structure 1000 (e.g., removed from portions of structure 1600 above barrier 1505).

In some cases, at least a portion of the dielectric formed in the thinner spaces may be removed from at least one thinner tier of structure 1600 above barrier 1505. As shown, the dielectric from at least the first thinner space from the top of structure 1600 may be removed. For example, dielectric 1105 may be removed from space 920, while the dielectric in thinner spaces below barrier 1505 (e.g., in space 940, space 950) may remain based on barrier 1505 preventing their removal.

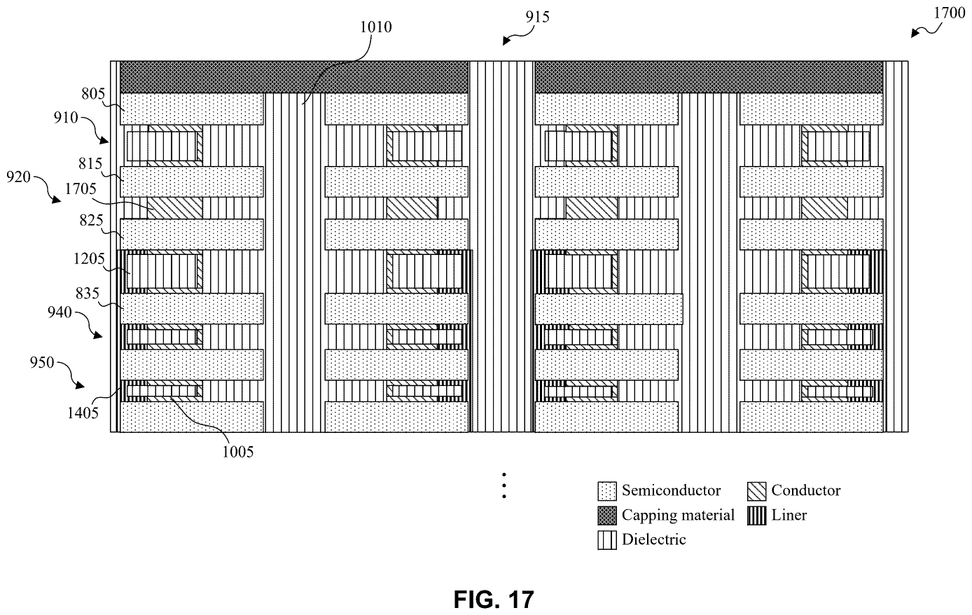

FIG. 17 may depict a structure 1700 associated with the fabrication of a bitline multiplexor (mux) integrated within a stacked memory module. The arrangement of structure 1700 is designed to improve the sense margin of memory sensing amplifiers by reducing the load on the sense amplifiers without increasing their number.

In the illustrated example, the barrier material (e.g., barrier 1505, carbon) may be removed. In some cases, barrier 1505 may be removed from gap 915 and insulator material (e.g., dielectric, silicon nitride) may be deposited in gap 915 (e.g., and other corresponding gaps). At least part of the capping material may be removed and a liner may be added (e.g., oxide fill, silicon nitride).

As shown, conductive material (e.g., metal, titanium nitride, etc.) may be deposited in or added to the space provided based on removing the dielectric from the first thinner spaces down from the top of structure 1700. For example, conductive material (e.g., conductor 1705) may be added to space 920 based on the removal of dielectric 1105 from space 920. Similarly, conductive material may be added to other thinner spaces of structure 1700 on the same tier or layer as space 920. Based on adding this conductive material, the gate metal of the two transistors of the bitline selector or keeper may be merged for the merged gate configuration.

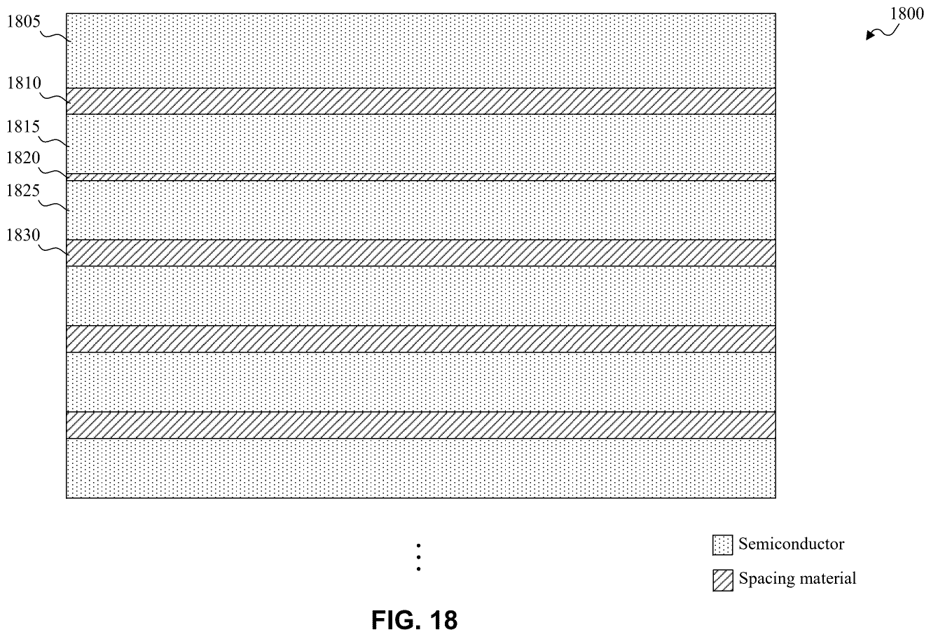

FIG. 18 depicts a layered structure 1800 representing at least a portion of a fabrication process for a bitline multiplexor (mux). For example, the depicted stack comprises alternating layers of semiconductors (e.g., silicon and silicon germanium (SiGe)), where the layers may be arranged to facilitate the formation of the bitline mux within a stacked memory module.

In the illustrated example, the stack comprises multiple semiconductor layers (e.g., 1805, 1815, 1825, silicon layers) and multiple spacing layers (e.g., layers 1810, 1820, 1830, silicon germanium (SiGe) layers). As shown, layers 1805, 1815, 1825, etc., exhibit relatively thicker dimensions compared to the relatively thinner layers 1810, 1820, 1830, etc. In some examples, the topmost layer 1805 may be formed with a thickness greater than that of the other semiconductor layers (e.g., other silicon layers). In some cases, some semiconductor layers (e.g., layer 1815, 1825, etc.) may serve as the primary material for forming transistor channels and other active components of structure 1800.

As shown, some spacing layers near the top of the stack may be formed with a thinner profile (e.g., less than 30 nanometers) relative to the other spacing layers (e.g., 30 to 80 nanometers). This differentiation in spacing layer thickness may enable control over layer spacing during subsequent fabrication steps.

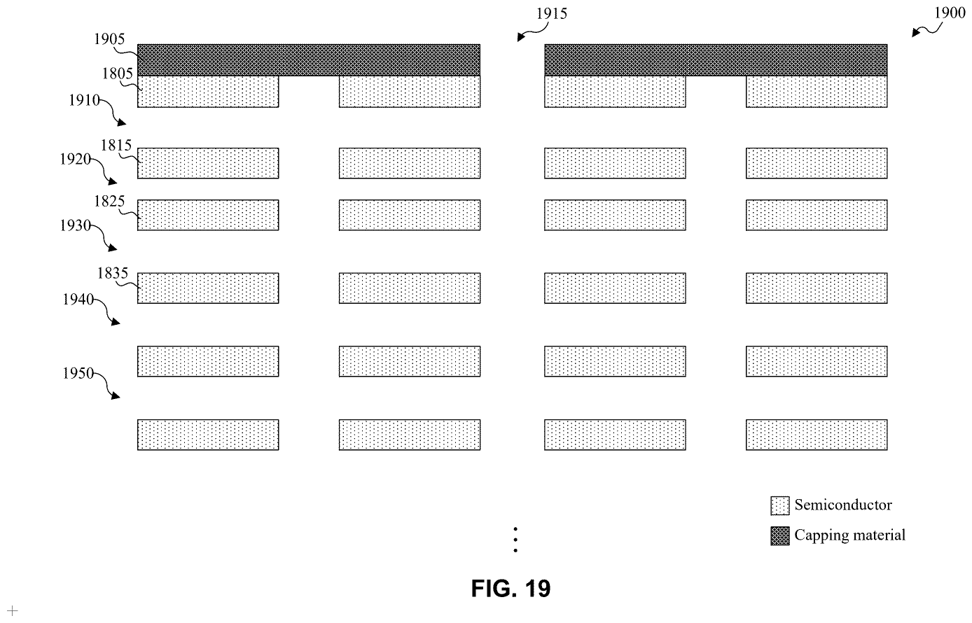

FIG. 19 illustrates a structure 1900 associated with the fabrication of a stacked memory module configuration with bitline multiplexor. FIG. 19 may depict the removal of spacing material from the layered structure 1900 and the thinning of semiconductor layers. The removal process may facilitate differentiated spacing between semiconductor layers, thereby enabling the deposition of distinct materials and supporting the fabrication of high-density memory systems. As shown, the depicted fabrication process may result in the silicon layers being divided into two or more segments with gaps between the segments (e.g., four segments with three gaps being depicted).

In the illustrated example, the semiconductor at 1805, 1815, 1825, etc., may be thinned. For example, a portion of the layers of semiconductor may be etched, etc. Accordingly, the thickness (e.g., vertical thickness) of the semiconductor layers may be reduced. In some cases, an oxide (e.g., gate oxide) may be deposited on one or more surfaces of the semiconductor at 1805, 1815, 1825, etc.

In some examples, the spacing material that was at spaces 1910, 1920, 1930, 1940, etc., may be removed from structure 1900. As shown, the removal process (e.g., etching process) may form a gap 1915 between the elements of structure 1900. As shown, space 1920 may be less or thinner than other spaces. For example, spaces 1910, 1930, 1940, and 1950 may be greater in height than space 1920.

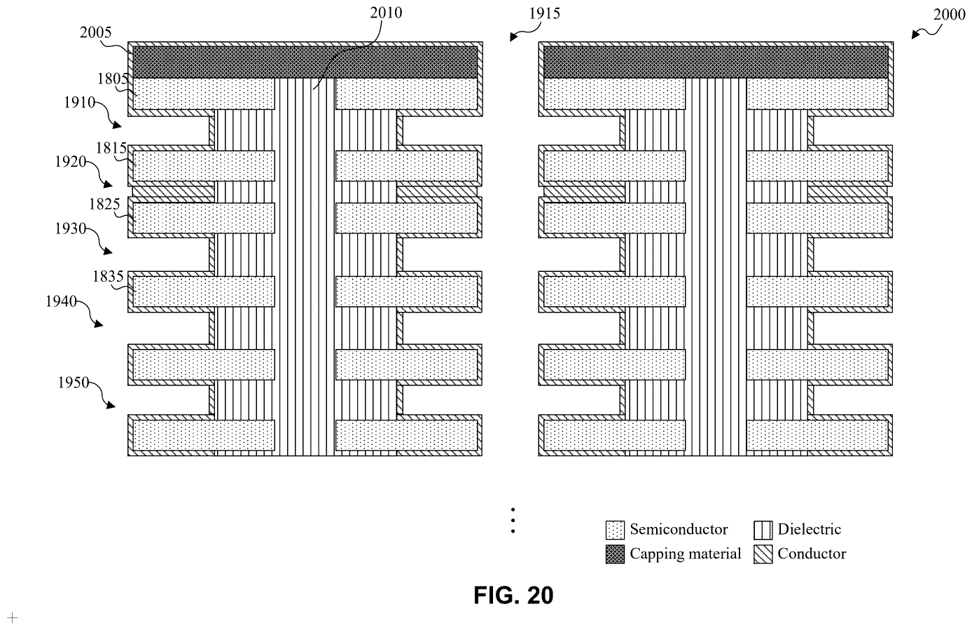

FIG. 20 depicts a structure 2000 associated with the fabrication of a bitline multiplexor (mux) integrated within a stacked memory system. For example, structure 2000 may depict adding material in a process of fabricating a stacked memory system with a bitline mux.

In the illustrated example, a conductive material (e.g., conductor 2005) may be added to or deposited over one or more exposed surfaces of structure 2000. As shown, an insulator material (e.g., dielectric 2010) may be added to inner spaces of structure 2000.

In some cases, conductor 2005 may include a metal (e.g., titanium nitride). As shown, conductor 2005 may coat semiconductor layers 1805, 1815, 1825, etc. Based on the space in the thicker spaces at 1910, 1930, etc., conductor 2005 may coat the surfaces in spaces 1910, 1930, etc., but not fill in the spaces 1910, 1930, etc. Accordingly, the conductive material in the thicker spaces (e.g., 1910, 1930, 1940, 1950) may not be merged due to the thicker spacing in these spaces.

Based on the thinner space at 1920 (e.g., and other thinner spaces), the conductive material may fill in at least a portion of the open space of the thinner spaces. Based on the thinner space, the conductive material may be merged in the one or more thinner spaces. For example, conductor 2005 may be merged in space 1920. The merged conductive material at space 1920 may be configured to be the merged gate metal for a bit selector or keeper cell.

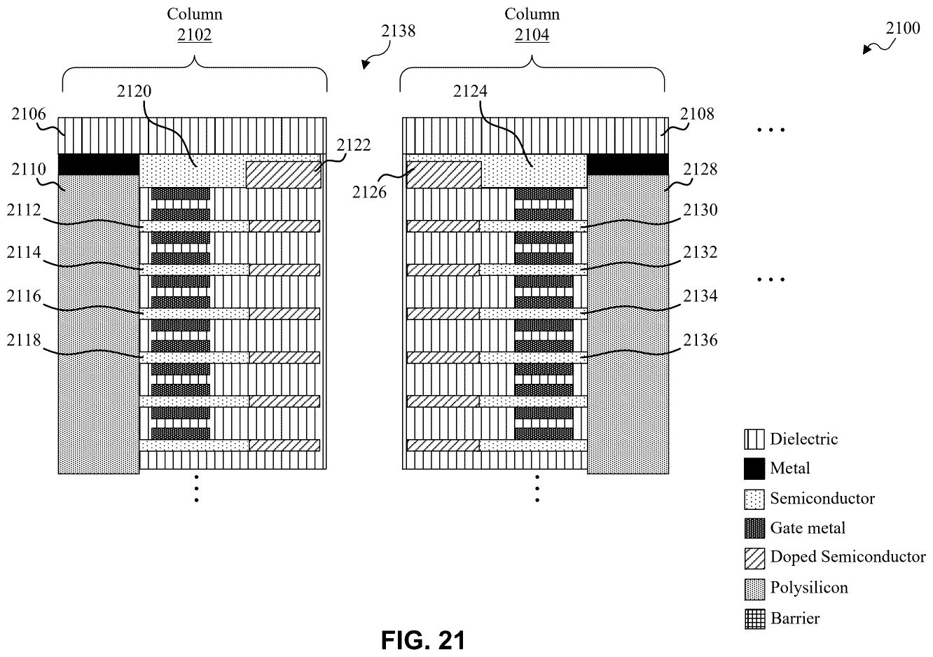

FIG. 21 may illustrate a structure 2100 associated with the fabrication of a bitline multiplexor (mux) integrated within a stacked memory system. For example, structure 2100 may depict the hierarchical structure of the bitline mux integrated in a stacked memory module based on a fabrication process.

In the illustrated example, structure 2100 may include column 2102 and column 2104. Column 2102 may be a first column of semiconductor tiers and column 2104 may be a second column of semiconductor tiers. Structure 2100 may include two or more such semiconductor tiers.

As shown, column 2102 may include a top layer of a (e.g., dielectric 2106), and column 2014 may include a top layer of a dielectric (e.g., dielectric 2108).

As shown, column 2102 may include a semiconductor layer 2120 that includes a block of doped semiconductor 2122 (e.g., block of n+ doped semiconductor). Similarly, column 2104 may include a semiconductor layer 2124 that includes a block of doped semiconductor 2126 (e.g., block of n+ doped semiconductor).

In the illustrated example, column 2102 may include bitline 2110, and column 2104 may include bitline 2128. In some cases, bitline 2110 or bitline 2128 may include a conductive material (e.g., polysilicon).

As shown, structure 2100 may include the formation of one or more transistors (e.g., transistors 2112-2118 of column 2102, transistors 2130-2136 of column 2104, etc.). As shown, at least a first portion of a given transistor may include a semiconductor (e.g., silicon) and at least a second portion of the given transistor may include a doped semiconductor (e.g., n-doped semiconductor).

In some cases, a removal process (e.g., etching process) may form a gap 2138 between column 2102 and column 2104 of structure 2100. As stated, structure 2100 may depict semiconductor tiers of one or more columns (e.g., column 2102, column 2104, etc.), and structure 2100 may include additional columns with gaps between the additional columns.

As shown, gap 2138 may be formed (e.g., based on removing or etching material) for a capacitor area of structure 2100. As shown, surfaces of structure 2100, including gap 2138, may be lined with a dielectric (e.g., oxide dielectric).

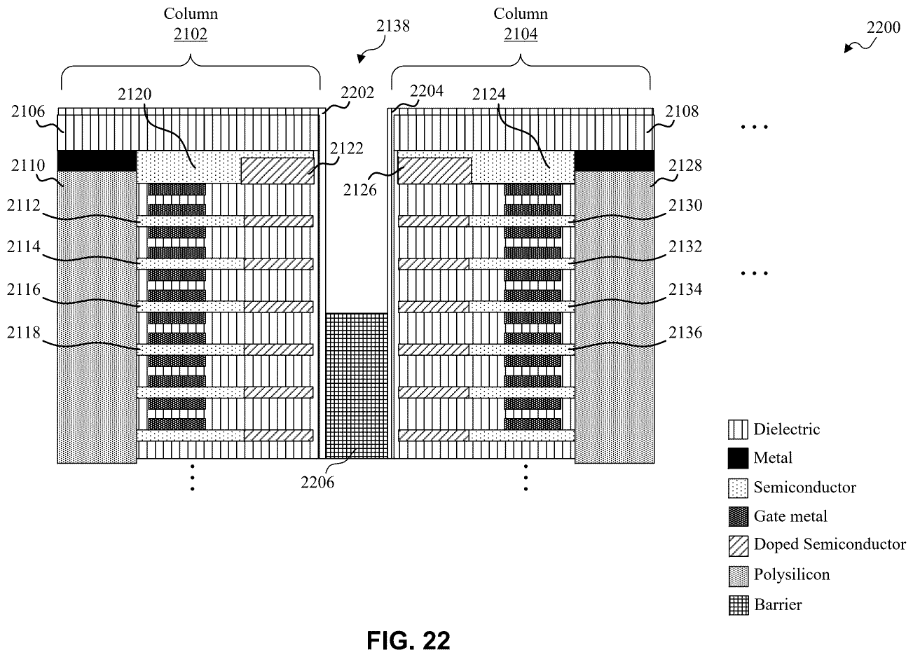

FIG. 22 may depict a structure 2200 associated with the fabrication of a bitline multiplexor (mux) integrated within a stacked memory system. For example, structure 2200 may depict the hierarchical structure of the bitline mux integrated in a stacked memory module based on a fabrication process.

In the illustrated example, surfaces of structure 2200, including gap 2138, may be lined with an additional dielectric different from the dielectric added in FIG. 21 (e.g., dielectric 2106). As shown, the additional dielectric may include dielectric 2202 added to components of column 2102 and dielectric 2204 added to components of column 2104. In some cases, the additional dielectric may include a nitride dielectric (e.g., silicon nitride).

As shown, at least a portion of gap 2138 may be filled with a barrier material (e.g., barrier 2206). In some cases, barrier 2206 may include a material (e.g., carbon) to form a fabrication barrier.

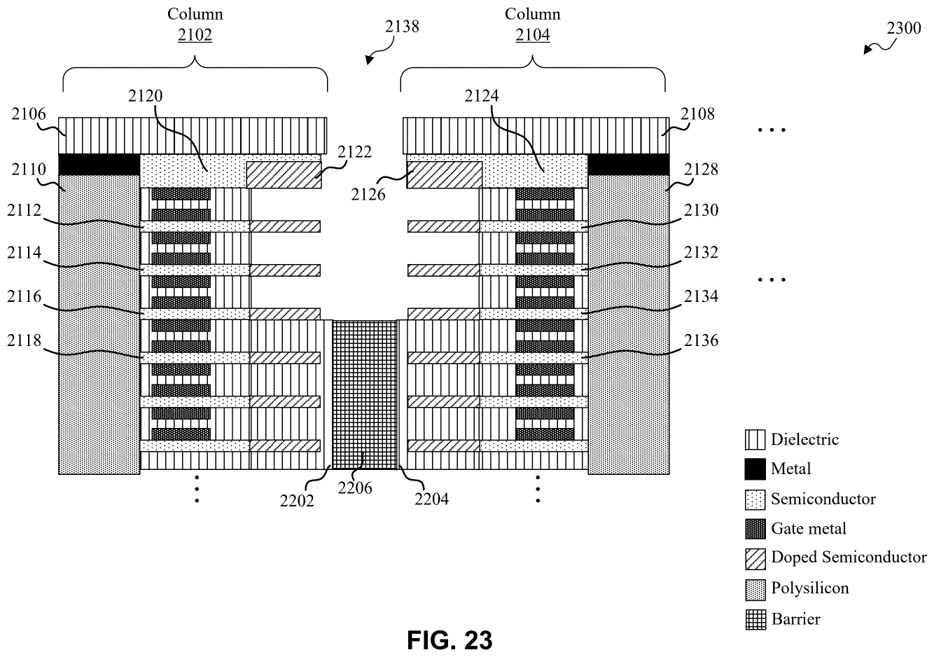

FIG. 23 may depict a structure 2300 associated with the fabrication of a bitline multiplexor (mux) integrated within a stacked memory system. For example, structure 2300 may depict the hierarchical structure of the bitline mux integrated in a stacked memory module based on a fabrication process.

In the illustrated example, at least a portion of dielectric 2202 and dielectric 2204 may be removed (e.g., portions of dielectric 2202 and dielectric 2204 above barrier 2206, portions from gap 2138).

In some cases, removing dielectric 2202 and dielectric 2204 from upper tiers of column 2102 and column 2104 may expose portions of the transistors above barrier 2206 (e.g., transistors 2112, 2114, 2116, 2130, 2132, 2134). In some cases, transistors of structure 2300, including these exposed transistors, may be covered or coated in a gate oxide (e.g., to insulate the transistors from gate metal). In some cases, removing dielectric 2202 and dielectric 2204 from upper tiers of column 2102 and column 2104 may expose portions of the gate oxide that covers the transistors above barrier 2206.

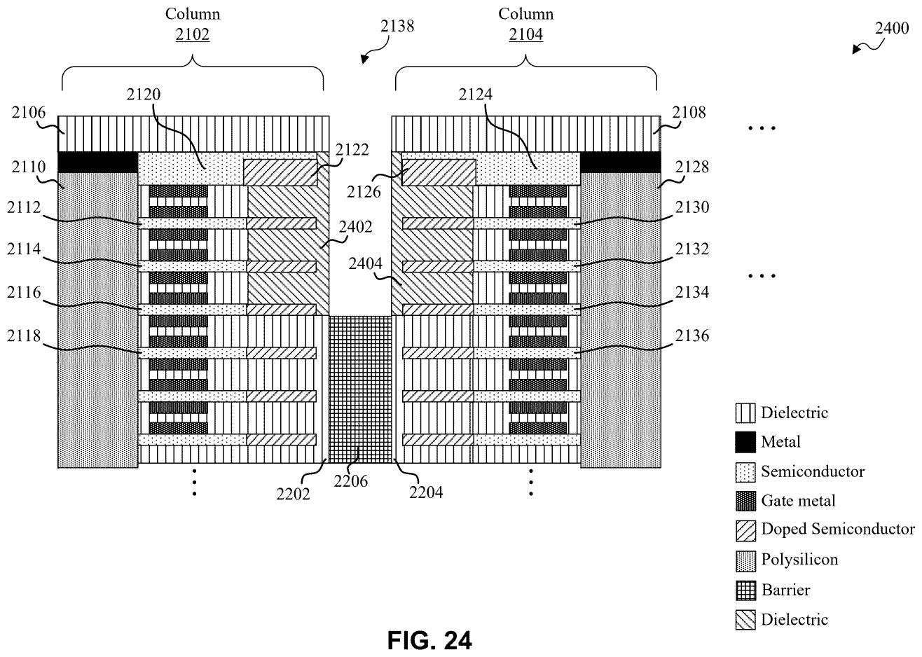

FIG. 24 illustrates a structure 2400 associated with the fabrication of a bitline multiplexor (mux) integrated within a stacked memory system. For example, structure 2400 may depict the hierarchical structure of the bitline mux integrated in a stacked memory module based on a fabrication process.

In the illustrated example, an additional dielectric (e.g., silicon oxycarbide) may be added to the space surrounding the upper tier transistors based on removing the portions of dielectric 2202 and dielectric 2204 above barrier 2206. For example, dielectric 2402 may be added to column 2102 and dielectric 2404 may be added to column 2104. As shown, dielectric 2402 may be added to spaces around transistors 2112, 2114, and dielectric 2404 may be added to spaces around transistors 2116, 2130, 2132, 2134.

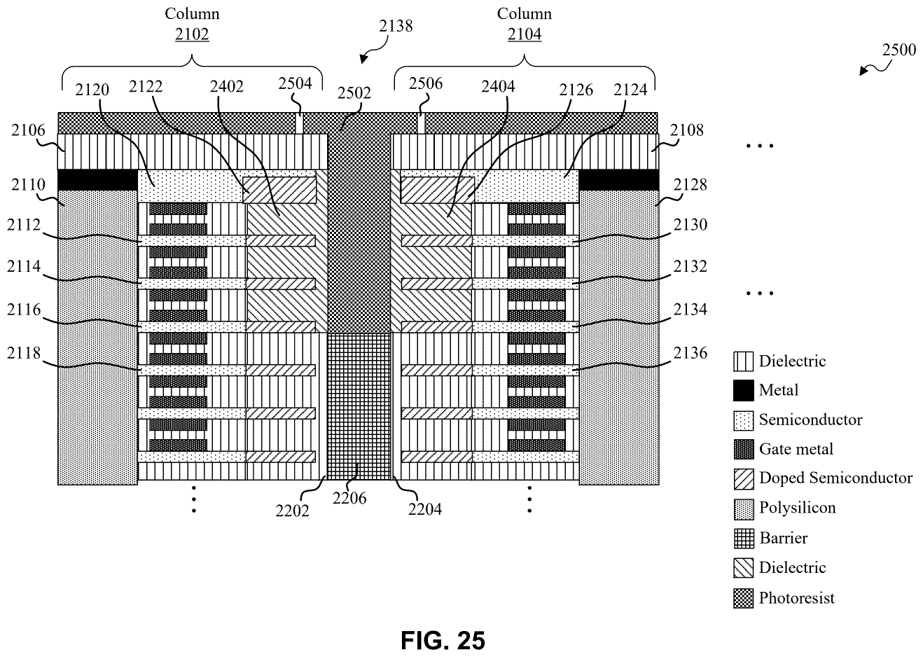

FIG. 25 depicts a structure 2500 associated with the fabrication of a bitline multiplexor (mux) integrated within a stacked memory system. For example, structure 2500 may depict the hierarchical structure of the bitline mux integrated in a stacked memory module based on a fabrication process.

In the illustrated example, an upper portion of gap 2138 may be filled with a protective material (e.g., photoresist 2502). As shown, photoresist 2502 may cover portions of dielectric 2106 and fill portions of gap 2138 above barrier 2206.

As shown, a portion of photoresist 2502 may be removed or etched at a location over doped semiconductor 2122 to form hole 2504. Similarly, a portion of photoresist 2502 may be removed or etched at a location over doped semiconductor 2126 to form hole 2506. In some cases, hole 2504 may be formed to allow a portion of layers of column 2102 below hole 2504 to be removed. Similarly, hole 2506 may be formed to allow a portion of layers of column 2104 below hole 2506 to be removed.

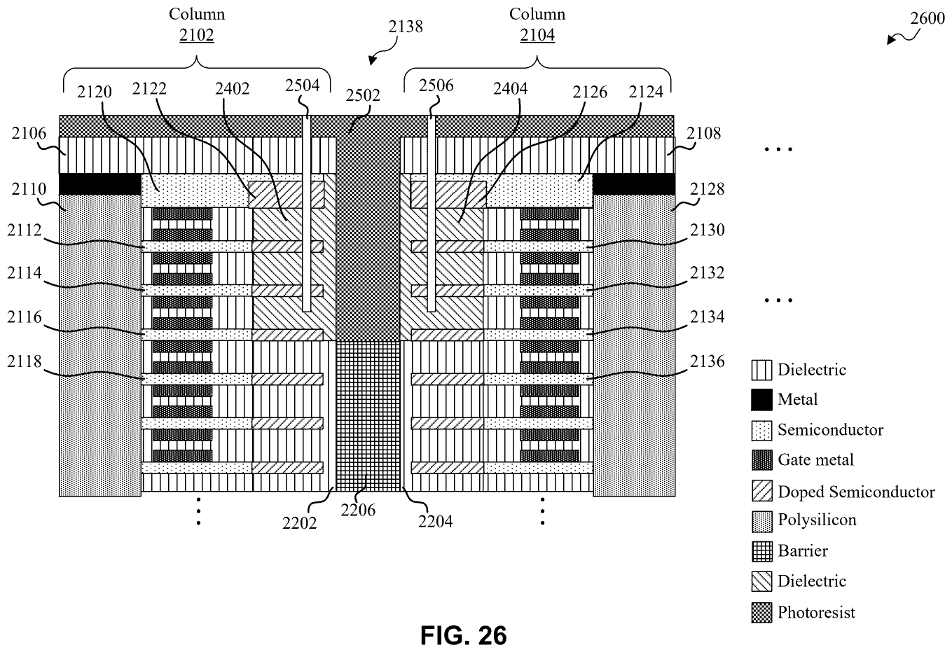

FIG. 26 illustrates a structure 2600 associated with the fabrication of a bitline multiplexor (mux) integrated within a stacked memory system. For example, structure 2600 may depict the hierarchical structure of the bitline mux integrated in a stacked memory module based on a fabrication process.

In the illustrated example, hole 2504 may be extended further into portions of column 2102. Similarly, hole 2506 may be extended further into portions of column 2104. For example, portions of dielectric 2106, doped semiconductor 2122, dielectric 2402, transistor 2112, and transistor 2114 may be removed (e.g., etched) to extend hole 2504. As shown, portions of dielectric 2108, doped semiconductor 2126, dielectric 2404, transistor 2130, and transistor 2132 may be removed (e.g., etched) to extend hole 2506. Accordingly, FIG. 26 depicts channels or holes formed via an etching process, where these holes can facilitate the formation of connectors for a bitline selector and a keeper cell.

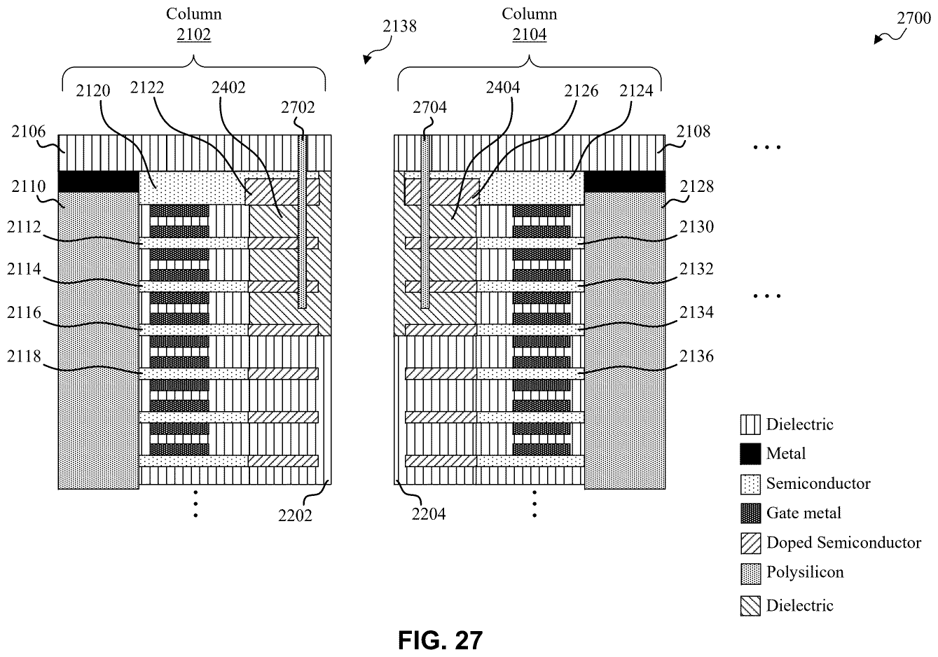

FIG. 27 depicts a structure 2700 associated with the fabrication of a bitline multiplexor (mux) integrated within a stacked memory system. For example, structure 2700 may depict the hierarchical structure of the bitline mux integrated in a stacked memory module based on a fabrication process.

In the illustrated example, photoresist 2502 may be removed from structure 2700. As shown, hole 2504 may be filled with a conductor 2702 (e.g., metal or polysilicon in the depicted example). Similarly, hole 2506 may be filled with conductor 2704 (e.g., metal or polysilicon in the provided example). As shown, barrier 2206 may be removed or etched from gap 2138.

In some cases, conductor 2702 may physically contact transistor 2112 and/or transistor 2114, enabling electrical signals to be communicated from conductor 2702 to transistors 2112 and 2114, and from transistors 2112 and 2114 to conductor 2702. As shown, conductor 2704 may physically contact transistor 2130 and/or transistor 2132, enabling electrical signals to be communicated from conductor 2704 to transistors 2130 and 2132, and from transistors 2130 and 2132 to conductor 2704.

Based on the depicted fabrication process, a bitline selector may be configured or formed based on forming the conductor 2702 to connect to transistor 2112 and transistor 2114. Similarly, a keeper cell may be configured or formed based on forming conductor 2704 to connect to transistor 2130 and transistor 2132.

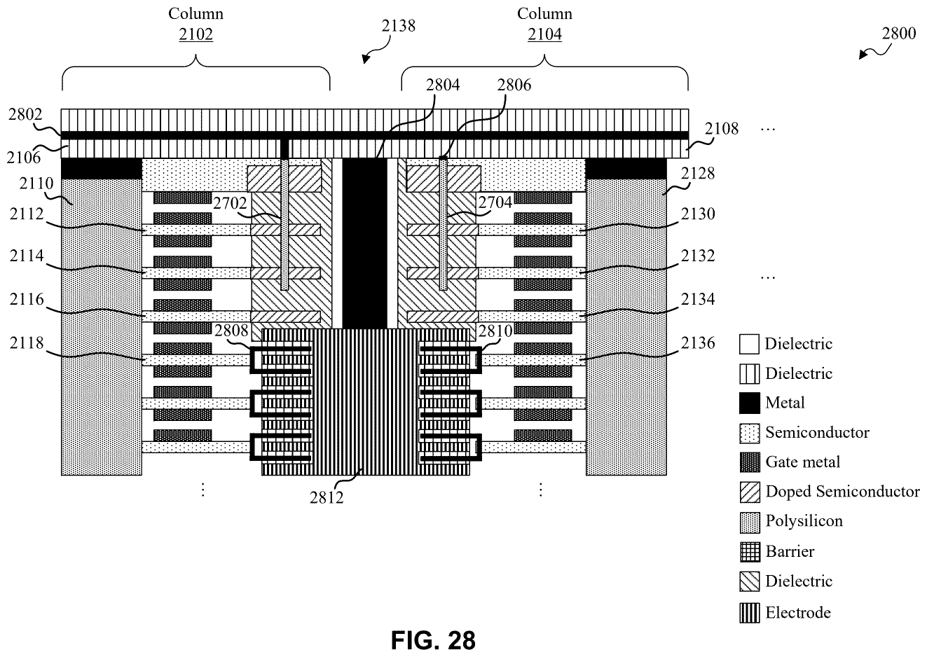

FIG. 28 depicts a structure 2800 associated with the fabrication of a bitline multiplexor (mux) integrated within a stacked memory system. For example, structure 2800 may illustrate a bitline multiplexor integrated within a stacked memory module.

It is noted that, components of column 2102 may be associated with a bit selector and components of column 2104 may be associated with a keeper cell. As shown, structure 2800 may include global bitline (GBL) 2802 connected to conductor 2702. Similarly, structure 2800 may include a bitline supply voltage (VBL) 2806 connected to conductor 2704.

It is noted that portions of white space depicted in FIG. 28 (e.g., portions of enclosed white space) may represent dielectric material. For example, the white space between transistor 2112 and transistor 2114, the white space between transistor 2130 and transistor 2132, etc., may depict spaces filled with dielectric material.

In the illustrated example, GBL 2802 may be formed in an upper layer of column 2102 and column 2104 (e.g., in or above dielectric 2106 and/or dielectric 2108). As shown, conductor 2702 may connect GBL 2802 to transistors 2112 and 2114, and to bitline 2110. Thus, adding conductor 2702 enables an electrical signal to travel between bitline 2110 and global bitline 2802.

As shown, VBL 2806 may connect to conductor 2704, connecting VBL 2806 to transistors 2130 and 2132, and to bitline 2128. Thus, adding conductor 2704 enables an electrical signal to travel between VBL 2806 and bitline 2128.

As shown, capacitor components may be added or formed in gap 2138. For example, cap 2804 (e.g., capping material, metal cap) and shared electrode 2812 may be formed in gap 2138. In some cases, capacitor electrodes may be added to transistors under transistor 2116 and/or added to transistors under transistor 2134. For example, electrodes 2808 (e.g. of a capacitor) may be added and connected to transistor 2118. Similarly, electrode 2810 (e.g. of a capacitor) may be added and connected to transistor 2136.

In some cases, transistor 2116 may be configured as a dummy floating tier below the bitline selector, which may include transistor 2112, transistor 2114, and conductor 2702. Thus, transistor 2116 may insulate the bitline selector from a memory cell (e.g., transistor 2118 and capacitor associated with electrodes 2808). Similarly, transistor 2134 may be configured as a dummy floating tier below the keeper cell, which may include transistor 2130, transistor 2132, and conductor 2704. Thus, transistor 2134 may insulate the keeper cell from a memory cell (e.g., transistor 2136 and capacitor associated with electrodes 2810). Accordingly, transistor 2116 and transistor 2134 can increase inter-tier dielectric (ITD) thickness, which improves electrical isolation and prevents charge leakage during memory operations.

Structure 2800 may illustrate a hierarchical structure of a stacked memory module, where inter-tier dielectric layers are employed to enhance electrical isolation between the various components and stacked tiers. These inter-tier dielectric layers play a role in preventing adverse field effects and ensuring the reliable operation of the bitline mux. Additionally, such layers may improve isolation between the stacked tiers, thereby further contributing to the performance and reliability of the bitline mux.

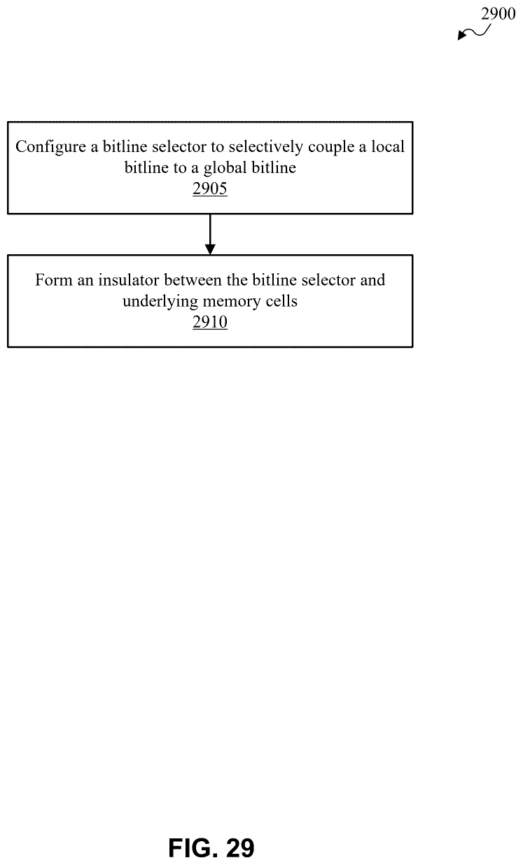

FIG. 29 depicts a flow diagram illustrating an example method 2900 associated with the disclosed systems, in accordance with example implementations described herein. In some configurations, one or more aspects of method 2900 may be implemented by or in conjunction with a fabrication device configured to perform a fabrication process that forms the features of bitline selectors and keeper cells described herein. The depicted method 2900 is just one implementation and one or more operations of method 2900 may be rearranged, reordered, omitted, and/or otherwise modified such that other implementations are possible and contemplated.

At 2905, method 2900 may include configuring a bitline selector to selectively couple a local bitline to a global bitline. For example, a fabrication device may configure or form a bitline selector to selectively couple a local bitline to a global bitline during a charge-sharing mode. The bitline selector may include at least one transistor having a source terminal coupled to the local bitline and a drain terminal connected to a conductive connector that is connected to the global bitline.

At 2910, method 2900 may include forming an insulator between the bitline selector and underlying memory cells. For example, the fabrication device may form an insulator between the bitline selector and a memory cell, where the insulator is configured to increase an inter-tier dielectric between the bitline selector and the memory cell.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wired and/or wireless communication device such as a switch, router, network interface controller, cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be wireless, wired, mobile, and/or stationary.

As used within this document, the term “communicate” is intended to include transmitting, or receiving, or both transmitting and receiving. Similarly, the bidirectional exchange of data between two devices (both devices transmit and receive during the exchange) may be described as ‘communicating’, when only the functionality of one of those devices is being claimed. The term “communicating” as used herein with respect to wired and/or wireless communication signals includes transmitting the wired and/or wireless communication signals and/or receiving the wired and/or wireless communication signals. For example, a communication unit, which is capable of communicating wired and/or wireless communication signals, may include a wired/wireless transmitter to transmit communication signals to at least one other communication unit, and/or a wired/wireless communication receiver to receive the communication signal from at least one other communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Some embodiments may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Some embodiments may be used in conjunction with one or more types of wireless communication signals and/or systems following one or more wireless communication protocols, for example, Radio Frequency (RF), Infrared (IR), Frequency-Division Multiplexing (FDM), Orthogonal FDM (OFDM), Time-Division Multiplexing (TDM), Time-Division Multiple Access (TDMA), Extended TDMA (E-TDMA), General Packet Radio Service (GPRS), extended GPRS, Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth™, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other embodiments may be used in various other devices, systems, and/or networks.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example, a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example, an FPGA or an ASIC. The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random-access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, for example, a CRT (cathode ray tube) or LCD (liquid crystal display) monitor, for displaying information/data to the user and a keyboard and a pointing device, for example, a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example, as an information/data server, or that includes a middleware component, for example, an application server, or that includes a front-end component, for example, a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example, a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example, an HTML page) to a client device (for example, for purposes of displaying information/data to and receiving user input from a user interacting with the client device). Information/data generated at the client device (for example, a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples as set forth herein will come to mind to one skilled in the art to which these embodiments pertain to having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A system comprising:
an array of memory cells;
a global bitline;
a local bitline;
a bitline multiplexor comprising a bitline selector configured to selectively couple the local bitline to the global bitline, the bitline selector including at least one transistor having a source terminal coupled to the local bitline and a drain terminal connected to a conductive connector that is connected to the global bitline; and
an insulator positioned adjacent to the bitline selector and adjacent to a memory cell.

2. The system of claim 1, wherein:
the bitline selector comprises a first transistor and a second transistor, and
a gate of the first transistor is merged with the gate of the second transistor.

3. The system of claim 1, wherein:
the bitline selector comprises a first transistor and a second transistor, and
a gate of the first transistor is connected to the gate of the second transistor at a wordline page region.

4. The system of claim 1, wherein the insulator comprises a dummy floating tier positioned adjacent to a transistor of the bitline selector.

5. The system of claim 4, wherein the dummy floating tier comprises a dummy transistor that is positioned adjacent to the at least one transistor of the bitline selector and a transistor of the memory cell.

6. The system of claim 1, wherein:
the bitline selector selectively couples the local bitline to the global bitline during a charge-sharing mode, and
a charge sharing enable signal enables the bitline selector during the charge-sharing mode.

7. The system of claim 6, wherein the charge sharing enable signal disables the bitline selector during a precharge mode.

8. The system of claim 6, wherein the bitline selector is formed on one or more tiers of a memory module such that, during the charge-sharing mode, the bitline selector is activated to connect the local bitline electrically to the global bitline for transfer of a voltage level of the memory cell to a sense amplifier, the memory cell comprising a third transistor and a capacitor.

9. A system comprising:
an array of memory cells;
a local bitline;
a bitline multiplexor comprising a keeper cell configured to selectively couple the local bitline to a bitline supply voltage, the keeper cell including at least one transistor having a source terminal coupled to the local bitline and a drain terminal connected to a conductive connector that is connected to the bitline supply voltage; and
an insulator positioned adjacent to the keeper cell and adjacent to a memory cell.

10. The system of claim 9, wherein:
the keeper cell comprises a first transistor and a second transistor, and
a gate of the first transistor is merged with the gate of the second transistor.

11. The system of claim 9, wherein:
the keeper cell comprises a first transistor and a second transistor, and
a gate of the first transistor is connected to the gate of the second transistor at a wordline page region.

12. The system of claim 9, wherein the insulator comprises a dummy floating tier that includes a dummy transistor positioned adjacent to a transistor of the keeper cell and adjacent to a transistor of the memory cell.

13. The system of claim 9, wherein the keeper cell selectively couples the local bitline to the bitline supply voltage during a precharge mode.

14. The system of claim 13, wherein a precharge enable signal enables the keeper cell during the precharge mode.

15. The system of claim 14, wherein the precharge enable signal disables the keeper cell during a charge-sharing mode.

16. The system of claim 14, wherein the keeper cell is formed on one or more tiers of a memory module such that, during the precharge mode, the keeper cell is activated to connect the local bitline electrically to the bitline supply voltage to refresh the local bitline.

17. A method of fabricating a bitline multiplexor for a memory system, the method comprising:
configuring a bitline selector to selectively couple a local bitline to a global bitline, the bitline selector including at least one transistor having a source terminal coupled to the local bitline and a drain terminal connected to a conductive connector that is connected to the global bitline; and
forming an insulator adjacent to the bitline selector and adjacent to a memory cell, the insulator being configured to increase an inter-tier dielectric between the bitline selector and the memory cell.

18. The method of claim 17, wherein:
the bitline selector comprises a first transistor and a second transistor, and
a gate of the first transistor is merged with the gate of the second transistor.

19. The method of claim 17, wherein:
the bitline selector comprises a first transistor and a second transistor, and
a gate of the first transistor is connected to the gate of the second transistor at a wordline page region.

20. The method of claim 17, wherein the insulator comprises a dummy floating tier positioned adjacent to the bitline selector, the memory cell comprising a third transistor and the dummy floating tier comprising a dummy transistor.
